(19) United States
(12) Patent Application Publication
(10) Pub. No.: US 2025/0359420 A1
(43) Pub. Date: Nov. 20, 2025

(54) DISPLAY PANEL AND PREPARATION METHOD THEREFOR, DISPLAY APPARATUS AND TILED DISPLAY APPARATUS

(71) Applicants: BOE MLED Technology Co., Ltd., Beijing (CN); BOE Technology Group Co., Ltd., Beijing (CN)

(72) Inventors: Mingming JIA, Beijing (CN); Jing WANG, Beijing (CN); Lili WANG, Beijing (CN); Sha FENG, Beijing (CN); Shiwei HAN, Beijing (CN); Huan WANG, Beijing (CN); Chao LIU, Beijing (CN); Ming ZHAI, Beijing (CN)

(73) Assignees: BOE MLED Technology Co., Ltd., Beijing (CN); BOE Technology Group Co., Ltd., Beijing (CN)

(21) Appl. No.: 18/860,762

(22) PCT Filed: Dec. 29, 2023
(86) PCT No.: PCT/CN2023/143252

§ 371 Date: Oct. 28, 2024

(30) Foreign Application Priority Data
Feb. 27, 2023 (CN) 202310212532.0

(51) Int. Cl. H10H 29/85; H01L 25/16; H10H 29/01

(52) U.S. Cl. CPC H10H 29/857; H01L 25/167; H10H 29/0364

(57) ABSTRACT

A display panel and a preparation method therefor, a display apparatus, and a tiled display apparatus are provided. The display panel includes: a substrate including a first surface and a second surface opposite to each other, and a plurality of side surfaces which include at least one selected side surface and connect the first surface with the second surface; a plurality of connecting leads each including a first lead segment located on the first surface, a second lead segment located on the selected side surface, and a third lead segment and a fourth lead segment located on the second surface; a protective layer at least covering side surfaces of the first, second, third and fourth lead segments and a transfer layer covering a surface of the fourth lead segment away from the substrate and electrically connected to the fourth lead segment.

This application claims the priority of Chinese Patent Application No. 202310212532.0, filed on Feb. 27, 2023, the entire content of which is incorporated in this application by reference.

### TECHNICAL FIELD

The present disclosure relates to the field of display technology, and in particular, to a display panel and a preparation method therefor, a display apparatus and a tiled display apparatus.

### BACKGROUND

MLED (Micro Light-emitting Diode, or Mini Light-emitting Diode) micro display has received widespread attention as a third-generation display technology. Currently, due to a problem of a yield of a mass transfer, it is impossible to manufacture a large-size display apparatus through one time. Usually, a method of tiling small-size display apparatuses is adopted for assembling to form a large-size tiled display apparatus.

In order to reduce a size of a border of a display apparatus and reduce a width of a seam of a tiled display apparatus, a wiring provided on a side surface of a display panel may be adopted for a current single display panel to achieve a connection between a wiring on a display surface and a driver (e.g., a flexible circuit board or a driving chip) provided on a non-display surface, such that when a plurality of display panels are combined to form a larger-size tiled display apparatus, a spacing between adjacent display panels can be smaller, thereby enhancing display quality.

### SUMMARY

In an aspect, a display panel is provided. The display panel includes: a substrate, a plurality of connecting leads, a protective layer and a transfer layer. The substrate includes a first surface and a second surface opposite to each other, and a plurality of side surfaces connecting the first surface and the second surface. The plurality of side surfaces include at least one selected side surface. The second surface includes a fan-out region and a bonding region, and the fan-out region is closer to the selected side surface compared to the bonding region.

The connecting leads include a first lead segment located on the first surface, a second lead segment located on the selected side surface, and a third lead segment and a fourth lead segment located on the second surface; and the first lead segment, the second lead segment, the third lead segment and the fourth lead segment are connected sequentially. The third lead segment is located in the fan-out region, and the fourth lead segment is located in the bonding region. The protective layer covers at least side surfaces of the first lead segment, the second lead segment, the third lead segment, and the fourth lead segment. The transfer layer covers a surface of the fourth lead segment away from the substrate and is electrically connected to the fourth lead segment.

In some embodiments, a plurality of fourth lead segments of the plurality of connecting leads are arranged in parallel and at intervals along a first direction. The protective layer includes a fourth portion at least located in the bonding region, the fourth portion includes a plurality of capping patterns arranged in parallel and at intervals along the first direction, both sides of each fourth lead segment are provided with the capping pattern, and the capping pattern at least cover a side surface of the fourth lead segment at a corresponding side. The transfer layer includes a plurality of transfer parts, one transfer part is provided between every two adjacent capping patterns, and the transfer part is connected to two capping patterns adjacent to the transfer part.

In some embodiments, the capping pattern overlaps with an edge portion where a side surface of the fourth lead segment is located; and/or, a size of the transfer part in the first direction is less than a size of the fourth lead segment in the first direction.

In some embodiments, the protective layer includes a third portion at least located in the fan-out region, and the third portion is a continuous film layer along the first direction. An edge portion of the third portion away from the selected side surface overlaps with an edge portion of the capping pattern close to the selected side surface.

In some embodiments, a thickness of the third portion is greater than a thickness of the capping pattern.

In some embodiments, a thickness of the fourth part is less than or equal to 5 μm.

In some embodiments, a boundary of the fourth lead segment away from the selected side surface is closer to the selected side surface compared to a boundary of the capping pattern away from the selected side surface; and/or a boundary of the fourth lead segment close to the selected side surface is farther away from the selected side surface compared to a boundary of the capping pattern close to the selected side surface.

In some embodiments, along the first direction, a maximum value of a spacing between two adjacent capping patterns is less than or equal to a size of the fourth lead segment, and a minimum value of a spacing between two adjacent capping patterns is less than or equal to a size of the transfer part by 1.1 times.

In some embodiments, the protective layer includes a first portion located on the first surface, the first portion includes a first sublayer and a second sublayer alternately provided along a second direction, and the second direction is perpendicular to the selected side surface. Along the second direction, an edge portion of the first sublayer overlaps with an edge portion of the second sublayer close to the edge portion of the first sublayer.

In some embodiments, the protective layer includes a first portion located on the first surface, a second portion located on the second surface, and a third portion located in the fan-out region of the second surface. An edge portion of the first portion is connected to or overlaps with an edge portion of the second portion close to the edge portion of the first portion. An edge portion of the second portion is connected to or overlaps with an edge portion of the third portion close to the edge portion of the second portion.

In some embodiments, the display panel further includes: a flexible circuit board electrically connected to the transfer layer.

In another aspect, a display apparatus is provided. The display apparatus includes the display panel described as any of the embodiments described above; and a driving circuit board electrically connected to the display panel. The driving circuit board is configured to drive the display panel to display a picture.

In yet another aspect, a tiled display apparatus is provided. The tiled display apparatus includes a plurality of display panels tiled to each other described as any of the embodiments described above.

In yet another aspect, a preparation method for a display panel is provided. The preparation method for a display panel includes the following steps.

A plurality of connecting leads are formed on a substrate. The substrate includes a first surface, a second surface, and a plurality of side surfaces connecting the first surface and the second surface, the plurality of side surfaces includes at least one selected side surface, the second surface includes a bonding region and a fan-out region, the fan-out region is closer to the selected side surface compared to the bonding region; the connecting leads include a first lead segment located on the first surface, a second lead segment located on the selected side surface, and a third lead segment and a fourth lead segment located on the second surface; the first lead segment, the second lead segment, the third lead segment and the fourth lead segment are connected sequentially; and the third lead segment is located in the fan-out region, and the fourth lead segment is located in the bonding region.

A protective layer is formed by adopting a method of multiple printings. The protection layer at least covers side surfaces of the first lead segment, the second lead segment, the third lead segment, the fourth lead segment.

A transfer layer is formed. The transfer layer covers a surface of the fourth lead segment away from the substrate and is electrically connected to the fourth lead segment.

In some embodiments, forming the protective layer by adopting the method of multiple printings and forming the transfer layer includes the following steps.

A first portion of the protective layer is formed on the first surface through at least one printing.

A second portion of the protective layer is formed on the selected side surface through one printing.

A fourth portion of the protective layer is formed on the bonding region of the second surface through multiple printings. The fourth portion includes a plurality of capping patterns arranged in parallel and at intervals along a first direction, and both sides of each fourth lead segment are provided with a capping pattern, and the capping patterns at least cover a side surface of the fourth lead segment at a corresponding side; and the first direction is an arrangement direction of a plurality of fourth lead segments of the plurality of connecting leads.

A transfer layer is formed on the bonding region of the second surface through multiple printings. The transfer layer includes a plurality of transfer parts, one transfer part is provided between every two adjacent capping patterns, and the transfer part is connected to the two cover parts adjacent to the transfer part.

A third portion of the protection layer is formed on the fan-out region of the second surface through at least one printing.

A protective layer is formed through multiple printings. It can be understood that it effectively increases an area of the protective layer, such that a coverage region of the protective layer is larger, the protective layer can better cover the connecting leads, avoiding the problem of affecting the conductivity of the connecting lead due to water and oxygen corrosion caused by the connecting lead contacting with air and/or water vapor. A transfer layer is provided to cover a portion of the fourth lead segment not covered by the fourth portion, such that the fourth lead segment is completely covered. Meanwhile, the transfer layer plays a role of connecting the fourth lead segment and the flexible circuit board, thereby making the connection between the fourth lead segment and the flexible circuit board more stable.

### BRIEF DESCRIPTION OF THE DRAWINGS

In order to explain technical solutions in the present disclosure more clearly, the accompanying drawings to be used in some embodiments of the present disclosure will be introduced briefly below. Obviously, the accompanying drawings in the following description are merely drawings of some embodiments of the present disclosure, and a person of ordinary skill in the art can obtain other drawings according to these drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display panel according to some embodiments.

FIG. 2 is a structural diagram corresponding to step S01 to step S04 of a preparation method provided according to some embodiments.

FIG. 3 is a flow diagram of a preparation method for a display panel according to some other embodiments.

FIG. 4 is a structural diagram corresponding to step S1 and step S2 according to a preparation method in FIG. 3.

FIG. 5 is a structural diagram of a display panel according to some other embodiments.

FIG. 6 is a flow chart of steps S21˜S24 and step S31 of a preparation method according to some embodiments.

FIG. 7 is another structural diagram corresponding to step 21 according to a preparation method in FIG. 6.

FIG. 8 is yet another structural diagram corresponding to step 21 according to a preparation method in FIG. 6.

FIG. 9 is a cross-sectional view obtained according to a section line AA in FIG. 8.

FIG. 10 is a structural diagram corresponding to step S23 according to a preparation method in FIG. 6.

FIG. 11 is a structural diagram corresponding to step S31 according to a preparation method in FIG. 6.

FIG. 12 is a structural diagram corresponding to step S24 according to a preparation method in FIG. 6.

FIG. 13 is a cross-sectional view obtained according to a section line BB in FIG. 12.

FIG. 14 is a schematic diagram of a display apparatus according to some embodiments.

FIG. 15 is a structural diagram of a tiled display apparatus according to some embodiments.

### DETAILED DESCRIPTION

The technical solutions in some embodiments of the present disclosure will be described clearly and completely with reference to the accompanying drawings, obviously, the described embodiments are merely some but not all embodiments of the present disclosure. All other embodiments obtained by a person of ordinary skill in the art based on embodiments of the present disclosure shall be included in the protection scope of the present disclosure.

Unless otherwise required by the context, the term “comprise” shall be interpreted throughout the specification and claims as open and inclusive, i.e., “comprises, but not limited to”. In the description of the specification, the terms “one embodiment”, “some embodiments”, “exemplary embodiments”, “examples” or “some examples”, etc., are intended to indicate that specific features, structures, materials or characteristics related to the embodiment or example are included in at least one embodiment or example disclosed herein. The schematic representation of the above terms does not necessarily refer to the same embodiment or example. In addition, the specific features, structures, materials, or characteristics described may be included in any appropriate manner in any one or more embodiments or examples.

Below, the terms “first” and “second” are only used for descriptive purposes and cannot be understood as indicating or implying relative importance or implying the number of technical features indicated. Thus, the features limited by the “first” and “second” may explicitly or implicitly include one or more of these features. In the description of the embodiments of the present disclosure, unless otherwise specified, the meaning of “a plurality of” refers to two or more.

When describing some embodiments, expressions such as “coupled” and “connected” and their derivatives may be used. The term ‘connected’ should be broadly understood, for example, “connected” may be a fixed connection, may also be a detachable connection, or a one-piece, may be directly connected or indirectly connected through an intermediate medium. The term “coupled” refers to direct physical or electrical contact between two or more components. The term “coupled” or “communicably coupled” may also refer to two or more components that do not have direct contact with each other, but still cooperate or interact with each other. The embodiments disclosed here are not necessarily limited to the contents herein.

“At least one of A, B, and C” has the same meaning as” at least one of A, B, or C “and includes the following combinations of A, B, and C: only A, only B, only C, a combination of A and B, a combination of A and C, a combination of B and C, and a combination of A, B, and C.

“A and/or B” includes the following three combinations: only A, only B, and a combination of A and B.

The usage of “applicable” or “configured to” herein implies an open and inclusive language, which does not exclude devices that are applicable or configured to perform additional tasks or steps.

As used herein, “about”, “roughly”, or “approximately” include the values described and the average value within an acceptable deviation range of a specific value, where the acceptable deviation range is determined by those of ordinary skill in the art taking into account the measurement being discussed and the errors associated with the measurement of a specific quantity (i.e., the limitations of the measurement system).

As used herein, “parallel”, “perpendicular”, and “equal” include the situations described and situations that are similar to the described situations, and the range of the similar situations is within an acceptable deviation range, where the acceptable deviation range is determined by those of ordinary skill in the art taking into account the measurement being discussed and the errors associated with the measurement of a specific quantity (i.e., the limitations of the measurement system). For example, “parallel” includes absolute parallel and approximate parallel, where the acceptable deviation range for approximate parallel can be within a deviation of 5°; “perpendicular” includes absolute perpendicular and approximate perpendicular, where the acceptable deviation range for approximate perpendicular can also be within a deviation of 5°, for example. “Equal” includes absolute equal and approximate equal, where that in the acceptable deviation range for approximate equal can be, for example, that a difference between the two equal to each other is less than or equal to 5% of any one of the two.

It should be understood that when a layer or component is referred to as being on another layer or a substrate, the layer or component may be directly on another layer or substrate, or there may be an intermediate layer between the layer or component and another layer or substrate.

Exemplary implementations are described herein with reference to cross-sectional and/or plan views as idealized illustrative drawings. In the drawings, the thickness of the layer and the area of the region have been enlarged for clarity. Therefore, it can be assumed of changes in the shape relative to the drawings due to factors such as manufacturing technology and/or tolerances. Therefore, the exemplary implementations should not be interpreted as limited to the shapes of the regions shown herein, but rather include shape deviations caused by, for example, manufacturing. For example, an etched region shown as a rectangle typically has a curved feature. Therefore, the regions shown in the drawings are essentially illustrative, and their shapes are not intended to show the actual shape of the region of the device, nor are they intended to limit the scope of the exemplary implementations.

In order to enhance product reliability and reduce a transportation cost and a maintenance cost, a method of tiling a plurality of small-size display apparatuses may be adopted to assemble and form a large-size display apparatus.

In order to avoid a fragmentation sense of a display picture due to tiling, it is necessary to reduce a size of a border of a single small-size display apparatus and reduce a width of a seam. The small-size display apparatus includes a display panel. For example, a wiring located on a display surface of the display panel may be connected to a circuit board (e.g., a flexible circuit board) provided on a non-display surface of the display panel through a side wiring, such that when a plurality of small-size display apparatuses are tiled to form a larger-size display apparatus, a spacing between adjacent small-size display apparatuses may be smaller, thereby enhancing display quality.

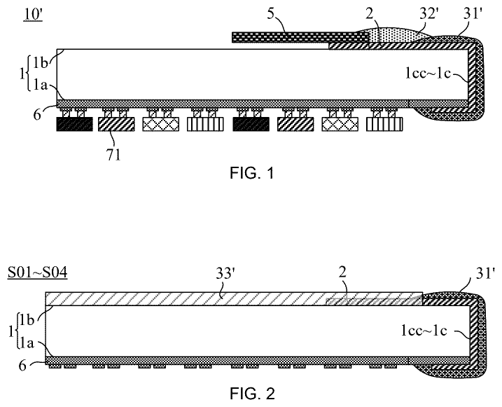

As shown in FIG. 1, in some embodiments, a display panel 10′ includes a substrate 1, a plurality of connecting leads 2, a driving line layer 6, a plurality of light emitting devices 71, a first barrier layer 31′, a second barrier layer 32′ and a flexible circuit board 5. The substrate 1 includes a first surface 1a and a second surface 1b that are opposite to each other, and a plurality of side surfaces 1c connecting the first surface 1a and the second surface 1b. The plurality of side surfaces 1c include at least one selected side surface 1cc.

As shown in FIG. 1, the driving line layer 6 is provided on the first surface 1a, and the plurality of light emitting devices 71 are provided on a side of the driving line layer 6 away from the substrate 1, and the plurality of light emitting devices 71 are electrically connected to the driving line layer 6, respectively. An end of a connecting lead 2 is electrically connected to the driving line layer 6, and the other end of the connecting lead 2 is electrically connected to the flexible circuit board 5. The flexible circuit board 5 is, for example, configured to issue a driving signal, and the driving signal is delivered to a light emitting device 71 through the connecting lead 2 and the driving line layer 6 in sequence, thereby controlling the light emitting device 71 to emit light.

As shown in FIG. 1, the first barrier layer 31′ covers a portion of the connecting lead 2 located on the first surface 1a and the selected side surface 1cc, and a portion of the connecting lead 2 located on the second surface 1b and close to the selected side surface 1cc. The second barrier layer 32′ covers a portion of the connecting lead 2 not covered by the flexible circuit board 5 and the first barrier layer 31′.

Exemplarily, the display panel 10′ mentioned above is formed through the following preparation method.

In S01, a driving line layer 6 is formed on a substrate 1, as shown in FIG. 2.

In S02, a plurality of connecting leads 2 are formed on the substrate 1, as shown in FIG. 2.

In S03, a first barrier layer 31′ is formed on a side of the plurality of connecting leads 2 away from the substrate 1, as shown in FIG. 2.

The first barrier layer 31′ is formed by adopting, for example, a pad printing process.

In S04, a third barrier layer 33′ is formed on a side of the connecting leads 2 away from the substrate 1, as shown in FIG. 2. The third barrier layer 33′ covers at least a portion of a connecting lead 2 that is not covered by the first barrier layer 31′.

In S05, a plurality of light emitting devices 71 are formed on a side of the driving line layer 6 away from the substrate 1, as shown in FIG. 1.

Exemplarily, a light emitting device 71 is, for example, a Micro-LED or a Mini-LED.

For example, high temperature reflow soldering is adopted to connect a pin of the light emitting device 71 to the driving line layer 6.

In S06, the third barrier layer 33′ is removed, as shown in FIG. 1.

The third barrier layer 33′ is, for example, a PI film (Polyimide Film).

In S07, a flexible circuit board 5 is bonded, as shown in FIG. 1. The flexible circuit board 5 is electrically connected to the connecting lead 2.

In S08, a second barrier layer 32′ is formed, as shown in FIG. 1.

Exemplarily, a material of the second barrier layer 32′ is, for example, a tuffy glue (peelable blue glue with a main component of generally acrylic resin, is cured by UV light and can have insulating, moisture-proof and protective effects after cured).

In the display panel 10′ formed through the preparation method mentioned above, the first barrier layer 31′ is prepared by adopting a pad printing process. Due to a limitation of a process, the first barrier layer 31′ cannot be made longer (i.e., a size of the first barrier layer 31′ in an extending direction from the first surface 1a, through the selected side surface 1cc, to the second surface 1b). The first barrier layer 31′ can only cover a portion of the connecting lead 2 located on the selected side surface 1cc, a portion of the connecting lead 2 located on the first surface 1a and a portion of the connecting lead 2 on the second surface 1b and close to the selected side surface 1cc.

Therefore, it is necessary to provide a third barrier layer 33′ to cover the portion of the connecting lead 2 not covered by the first barrier layer 31′, thereby avoiding the problem of affecting the conductivity of the connecting lead 2 due to water and oxygen corrosion caused by the connecting lead 2 contacting with air and/or water vapor in the preparation process of the display panel 10′. The third barrier layer 33′ is not included in a finally formed display panel, and the third barrier layer 33′ only protects portions of the plurality of connecting leads 2 located on the second surface 1b and not covered by the first barrier layer 31′.

In the preparation method mentioned above, a high temperature may be generated during the process of forming the plurality of light emitting devices 71 in step S05. The third barrier layer 33′ is, for example, a PI film. A material of the PI film will be denatured after being exposed to a high temperature, such that the connecting lead 2 is covered by the PI film, and a portion of the connecting lead 2 in contact with the PI film and the PI film will be tied to each other. In this way, when the PI film is removed in step S06, the portion of the connecting lead 2 tied to the PI film will be peeled from the substrate 1 together with the PI film, thereby resulting in a break of the connecting lead 2.

Meanwhile, portions where the PI film contacts with the substrate 1 (the PI film directly contacts with the substrate 1, or contacts with a remaining film layer structure provided between the substrate 1 and the connecting lead 2) will also be tied to each other when the PI film is heated, such that a problem that the PI film of the portion cannot be removed occurs. In this way, a part of the PI film remains on the substrate 1 and/or on the connecting lead 2. When a remaining PI film is located at a portion where the connecting lead 2 is connected to the flexible circuit board 5, a connection effect between the connecting lead 2 and the flexible circuit board 5 may be caused, thereby affecting the normal operation of the display panel 10′.

Based on this, the present disclosure provides a display panel and a preparation method therefor, a display apparatus, and a tiled display apparatus. The display panel and the preparation method therefor, the display apparatus, and the tiled display apparatus provided in the embodiments of the present disclosure are introduced below, respectively.

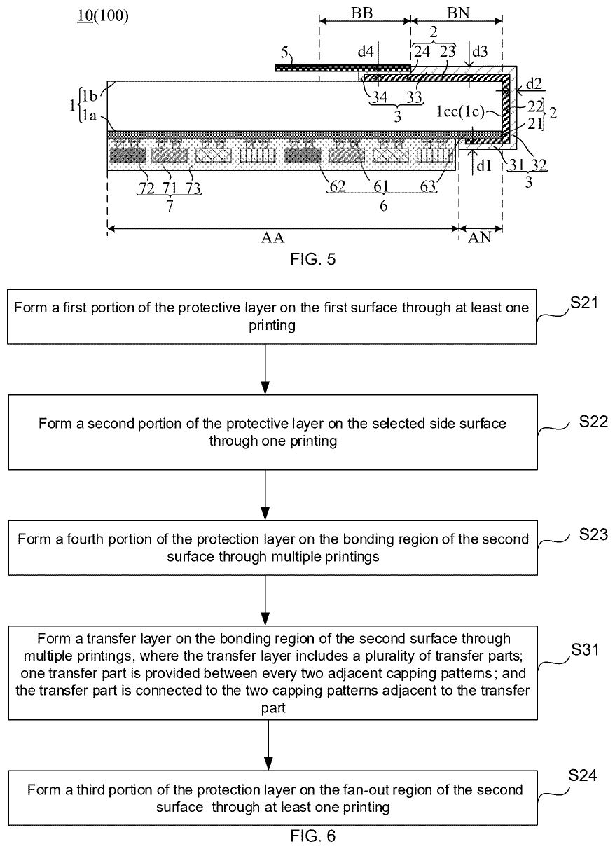

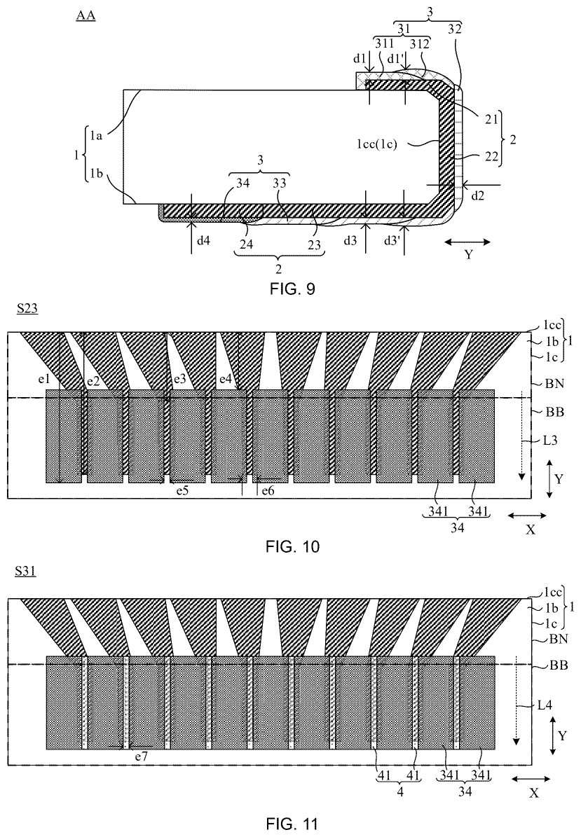

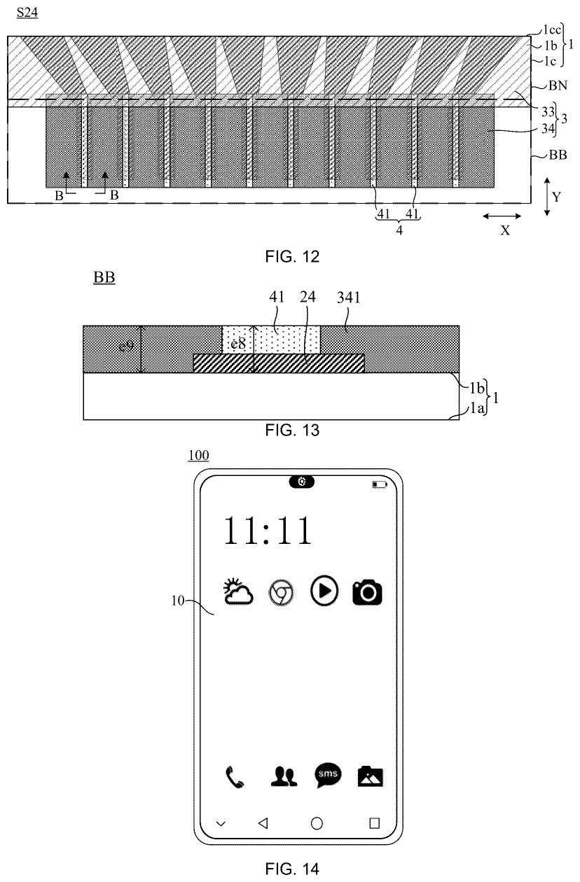

In the present disclosure, FIG. 5 is a cross-sectional structural diagram of a display panel 10 according to some embodiments, FIG. 9 is a cross-sectional view of a display panel 10 obtained according to a section line AA in FIG. 8, and FIG. 13 is a cross-sectional diagram of a display panel 10 obtained according to a section line BB in FIG. 12. In order to facilitate a clear description of a structural detail of a protective layer 3 and a transfer layer 4, structures such as a driving line layer 6, a light emitting device layer 7 and a flexible circuit board 5 of the display panel 10 in FIG. 9 and FIG. 13 are removed to obtain a structural diagram only including a substrate 1, a connecting lead 2, a protective layer 3 and a transfer layer 4, as shown in FIG. 9 and FIG. 13.

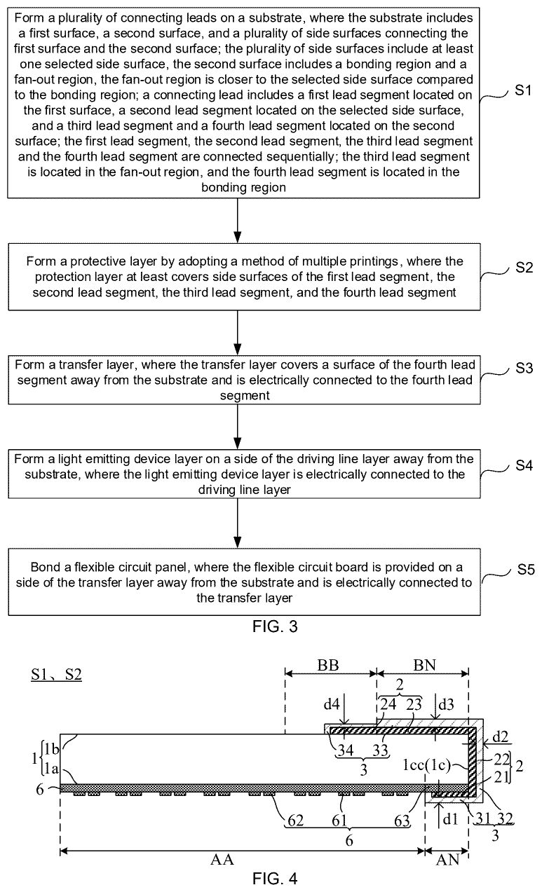

In some embodiments of the present disclosure, a preparation method for a display panel is provided. As shown in FIG. 3, the preparation method for a display panel includes the following steps: S1 to S5.

In S1, a plurality of connecting leads 2 are formed on a substrate 1, as shown in FIG. 4. The substrate 1 includes a first surface 1a, a second surface 1b, and a plurality of side surfaces 1c connecting the first surface 1a and the second surface 1b. The plurality of side surfaces 1c include at least one selected side surface 1cc. The second surface 1b includes a bonding region BB and a fan-out region BN. The fan-out region BN is closer to the selected side surface 1cc compared to the bonding region BB. A connecting lead 2 includes a first lead segment 21 located on the first surface 1a, a second lead segment 22 located on the selected side surface 1cc, and a third lead segment 23 and a fourth lead segment 24 located on the second surface 1b. The first lead segment 21, the second lead segment 22, the third lead segment 23 and the fourth lead segment 24 are connected sequentially. The third lead segment 23 is located in the fan-out region BN, and the fourth lead segment 24 is located in the bonding region BB.

Exemplarily, the plurality of connecting leads 2 are formed by adopting, for example, metal sputtering and a laser etching process.

It can be understood that the plurality of connecting leads 2 are provided close to the selected side surface 1cc.

Exemplarily, a connection manner of the connecting lead 2 with the substrate 1 is, for example, to form the connecting lead 2 directly on the surface of the substrate 1 (e.g., the first surface 1a, the second surface 1b and the selected side surface 1cc), such that the connecting lead 2 is directly connected to the substrate 1; or, a remaining film layer structure is provided between the connecting lead 2 and the surface of the substrate 1, and the connecting lead 2 is connected to the substrate 1 through the remaining film layer structure.

In some examples, respective portions of the connecting lead 2, such as the first lead segment 21, the second lead segment 22, the third lead segment 23 and the fourth lead segment 24, are connected to the substrate 1 in the same manner. That is, the first lead segment 21, the second lead segment 22, the third lead segment 23 and the fourth lead segment 24 are all directly connected to the substrate 1; or are all connected to the substrate 1 through the remaining film layer structure.

In some other examples, at least one of respective portions of the connecting lead 2, such as the first lead segment 21, the second lead segment 22, the third lead segment 23, and the fourth lead segment 24, are connected to the substrate 1 in different manners from remaining portions of the respective portions.

For example, the second lead segment 22 is directly formed on the selected side surface 1cc of the substrate 1; the remaining film layer structure is provided between the first lead segment 21 and the first surface 1a; and the remaining film layer structure is provided between the third and fourth lead segments 23 and 24 and the second surface 1b.

For another example, the second lead segment 22 is directly formed on the selected side surface 1cc of the substrate 1, the third lead segment 23 is directly formed on the second surface 1b, the remaining film layer structure is provided between the first lead segment 21 and the first surface 1a, and the remaining film layer structure is provided between the fourth lead segment 24 and the second surface 1b.

It should be noted that the bonding region BB is provided close to the selected side surfaces 1cc, a number of bonding regions BB is the same as a number of selected side surfaces 1cc, and the number of the bonding regions BB is the same as a number of fan-out regions BN.

Exemplarily, the plurality of side surfaces 1c including at least one selected side surface 1cc includes the following cases.

In some examples, one side surface 1c in the plurality of side surfaces 1c of the substrate 1 is the selected side surface 1cc. The plurality of connecting leads 2 are provided close to the selected side surface 1cc.

In some other examples, two or more side surfaces 1cc in the plurality of side surfaces 1c are selected side surfaces 1cc. The plurality of connecting leads 2 include a plurality of connecting lead groups, and each connecting lead group is provided close to one selected side surface 1cc.

In S2, a protective layer 3 is formed by adopting a method of multiple printings, as shown in FIG. 4. The protection layer 3 at least covers side surfaces of the first lead segment 21, the second lead segment 22, the third lead segment 23, and the fourth lead segment 24.

Exemplarily, the protective layer 3 is formed by adopting a printing process.

For example, the protective layer 3 includes a plurality of sublayers, and the plurality of sublayers constitute an entire continuous film layer. A plurality of sublayers are printed respectively to form a complete protective layer 3.

Exemplarily, a material of the protective layer 3 is an insulating material. The material of the protective layer 3 includes but is not limited to at least one of: ester resin and epoxy resin.

Exemplarily, the protective layer 3 covering at least the side surfaces of the first lead segment 21, the second lead segment 22, the third lead segment 23, and the fourth lead segment 24, refers to that the protective layer 3 covers a side surface of the first lead segment 21, a side surface of the second lead segment 22, a side surface of the third lead segment 23, and a side surface of the fourth lead segment 24; or, the protective layer 3 covers a side surface of the first lead segment 21 and at least a portion of a surface of the first lead segment 21 away from the substrate 1, a side surface of the second lead segment 22 and at least a portion of a surface of the second lead segment 22 away from the substrate 1, a side surface of the third lead segment 23 and at least a portion of a surface of the third lead segment 23 away from the substrate 1, and a side surface of the fourth lead segment 24 and at least a portion of a surface of the fourth lead segment 24 away from the substrate 1.

A protective layer 3 is performed to cover a corresponding portion of a connecting lead 2, and a problem is effectively avoided that conductivity is affected due to water and oxygen corrosion caused by the connecting lead 2 contacting with air and/or water vapor during a subsequent preparation process.

In S3, a transfer layer 4 is formed, as shown in FIG. 11 and FIG. 13. The transfer layer 4 covers a surface of the fourth lead segment 24 away from the substrate 1, and is electrically connected to the fourth lead segment 24.

Exemplarily, the transfer layer 4 is formed by adopting a printing process.

Exemplarily, a resistivity of a material of the transfer layer 4 is smaller than a resistivity of a material of the connecting lead 2.

Exemplarily, a material of the transfer layer 4 is required to be resistant to a high temperature and corrosion and has good electrical conductivity. The material of the transfer layer 4 includes but is not limited to at least one of: gold, silver and graphite.

It should be noted that, in the step of forming the transfer layer 4 by a printing process, a material to form the transfer layer 4 is moved onto the substrate 1 through an outlet of a printing device. A material for printing used when the transfer layer 4 is formed through printing is a fluid material, for example, the fluid material is formed from a mixed resin of nanoparticles of at least one of gold, silver and graphite.

A material resistant to a high temperature and corrosion resistance is adopted for the transfer layer 4. In this way, during a subsequent preparation process, even if a remaining film layer structure is not provided on a side of the transfer layer 4 away from the substrate 1 to protect the transfer layer 4, the performance of the transfer layer 4 itself will not be affected due to being heated at a high temperature during a process of forming the plurality of light emitting devices 71, and water and oxygen corrosion will not occur since the transfer layer 4 will not contact with air and/or water vapor. In a subsequent step S5, when the flexible circuit board 5 is connected to the transfer layer 4, the transfer layer 4 can ensure a stable connection between the fourth lead segment 24 and the flexible circuit board 5.

Exemplarily, the transfer layer 4 covering the surface of the fourth lead segment 24 away from the substrate 1 includes: covering an entire upper surface of the fourth lead segment 24, and covering a portion of an upper surface of the fourth lead segment 24. The upper surface of the fourth lead segment 24 refers to a surface of the fourth lead segment 24 away from the substrate 1.

Exemplarily, as shown in FIG. 3, step S4 and step S5 are further included after step S3.

In S4, a light emitting device layer 7 is formed on a side of the driving line layer 6 away from the substrate 1, as shown in FIG. 5. The light emitting device layer 7 is electrically connected to the driving line layer 6.

Exemplarily, as shown in FIG. 5, the light emitting device layer includes a plurality of light emitting devices 71. A pin of a light emitting device 71 is connected to the driving line layer 6 by adopting, for example, high temperature reflow soldering.

In some examples, as shown in FIG. 5, the light emitting device layer 7 further includes a plurality of driving chips 72. A driving chip 72 is configured to drive the light emitting device 71 to emit light. The driving chip 72 is, for example, a pixel driving chip, and a pin of the pixel driving chip is connected to the driving line layer 6 by adopting, for example, high temperature reflow soldering.

In yet some examples, as shown in FIG. 5, the light emitting device layer 7 further includes a protection film 73. The protection film 73 wraps the plurality of light emitting devices 71 and the plurality of driving chips 72.

A protective film 73 is provided to achieve a protective effect on the light emitting device 71 and the driving chip 72, thereby avoiding damage to the light emitting device 71 and the driving chip 72 during the subsequent preparation process and ensuring that the light emitting device layer 7 can emit light under control of a driving signal.

In S5, a flexible circuit panel 5 is bonded, as shown in FIG. 5. The flexible circuit board 5 is provided on a side of the transfer layer 4 away from the substrate 1 and is electrically connected to the transfer layer 4.

Exemplarily, the flexible circuit board 5 is connected to the transfer layer 4 through ACF (Anisotropic Conductive Film). For example, ACF is attached to a side of the transfer layer 4 away from the substrate 1, and then the flexible circuit board 5 is attached to the ACF, thereby achieving an electrical connection between the flexible circuit board 5 and the transfer layer 4.

It can be understood that the flexible circuit board 5 is electrically connected to fourth lead segments 24 of the plurality of connecting leads 2 through the transfer layer 4.

In the display panel 10 formed through the preparation method mentioned above, the protective layer 3 is formed by a method of multiple printings to make an entire structure of the protective layer 3 longer (i.e., a size of the protective layer 3 in an extension direction from the first surface 1a, through the selected side surface 1cc, to the second surface 1b), such that the side surfaces of the first lead segment 21, the second lead segment 22, the third lead segment 23 and the fourth lead segment 24 of the connecting lead 2 can be completely covered; and the transfer layer 4 covers a portion of the fourth lead segment 24 not covered by the protective layer 3. It can be understood that the protective layer 3 and the transfer layer 4 formed by adopting the preparation method mentioned above completely cover the connecting lead 2, thereby avoiding the problem of affecting the conductivity of the connecting lead 2 due to water and oxygen corrosion caused by the connecting lead 2 contacting with air and/or water vapor.

Compared with the preparation method provided in some embodiments, the protective layer 3 and the transfer layer 4 are provided to achieve a protective effect of the first barrier layer 31′, the second barrier layer 32′ and the third barrier layer 33′ on the connecting lead 2; and have a larger coverage area for the connecting lead 2, thereby achieving a better protective effect. Meanwhile, the step of forming the third barrier layer 32′ is omitted, thereby avoiding the problems that may occur when the third barrier layer 33′ is removed during the preparation process of the display panel, such as the connecting lead 2 being broken due to a portion of the connecting lead 2 being removed with the third barrier layer 33′, and affecting the connection effect of the connecting lead 2 with the flexible circuit board 5 due to remaining of a portion of the third barrier layer 33′.

Compared with the preparation method provided in some embodiments, the second barrier layer 32′ is provided to cover a portion of the connecting lead 2 that is not covered by the first barrier layer 31′ and the flexible circuit board 5, and this portion is exposed to an outside during the process of connecting the flexible circuit board 5 and the connecting lead 2. During this period, this portion may also be corroded by water and oxygen when contacting with air and/or water vapor, thereby affecting its conductivity. In some embodiments of the present disclosure, by providing a protective layer 3 and a transfer layer 4, the connecting lead 2 is kept in a covered state throughout the entire preparation process, effectively preventing the connecting lead 2 from contacting with air and/or water vapor, thereby better avoiding the problem of affecting the conductivity of the connecting lead 2 due to water and oxygen corrosion on the connecting lead 2.

In some embodiments, as shown in FIG. 5, the first surface 1a of the substrate 1 includes a display region AA and a peripheral region AN located at least on a side of the display region AA. Before step S1, step S11 is further included.

In S11, a driving line layer 6 is formed on the first surface 1a, as shown in FIG. 4.

Exemplarily, the first surface 1a includes, for example, a display region AA and a peripheral region AN located at least on a side of the display region AA.

The driving line layer 6 includes, for example, a pad layer and an electrode layer, and the pad layer is electrically connected to the electrode layer. The pad layer includes a first type of pad 61 located in the display region AA and a plurality of second type of pads 62, and the electrode layer includes a plurality of first electrodes 63 located in the peripheral region AN.

The first type of pad 61 is, for example, a device pad, and the second type of pad 62 is, for example, a driving pad. The light emitting device 71 is, for example, electrically connected to a first type of pad 61 (e.g., device pad), and the driving chip 72 is, for example, electrically connected to a second type of pad 62 (e.g., driving pad).

For example, high temperature reflow soldering is adopted for connecting a pin of the light emitting device 71 to the first type of pad 61, and/or high temperature reflow soldering is adopted for connecting the driving chip 72 to the second type of pad 62.

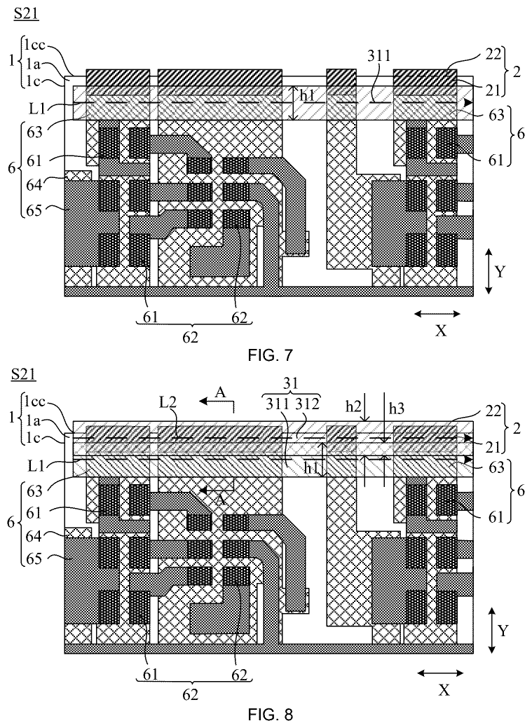

As shown in FIG. 7 and FIG. 8, the plurality of first electrodes 63 are provided, for example, close to the selected side surface 1cc of the substrate 1, and are arranged in parallel and at intervals along a first direction X.

Exemplarily, as shown in FIG. 7 and FIG. 8, the first lead segment 21 of each connecting lead 2 is electrically connected to, for example, one first electrode 63. An edge portion of the first lead segment 21 is connected to or overlaps with an edge portion of the first electrode 63 that is close to the edge portion of the first lead segment 21. It can be understood that a number of the connecting leads 2 may be the same as or different from a number of the first electrodes 63.

Exemplarily, as shown in FIG. 7 and FIG. 8, the driving line layer 6 further includes a first conductive layer and a second conductive layer, and the first conductive layer is electrically connected to the second conductive layer. The first conductive layer includes a plurality of first signal lines 64, and the second conductive layer includes a plurality of second signal lines 65. The pad layer is located on a side of the second conductive layer away from the substrate 1, and the pad layer is electrically connected to the second conductive layer.

Exemplarily, the first electrode 63 is provided in the same layer as a first signal line 64 and/or a second signal line 65.

In some examples, the second conductive layer is, for example, the aforementioned electrode layer, and the second conductive layer includes a plurality of first electrodes 63 and a plurality of second signal lines 65.

In some other examples, the first conductive layer is, for example, the aforementioned electrode layer, and the first conductive layer includes a plurality of first electrodes 63 and a plurality of first signal lines 64.

In yet some embodiments, the electrode layer includes a first conductive layer and a second conductive layer provided in a stacked manner. The first signal line 64 and the second signal line 65 have a single-layer film structure, and the first electrode 63 has a double-layer film structure. The first electrode 63 is electrically connected to the first signal line 64.

Each first electrode 63 is, for example, electrically connected to one first signal line 64. The flexible circuit board 5 is configured to issue a driving signal, and the driving signal is used to control the light emitting device 71 to emit light. The driving signal is delivered to the light emitting device 71 through the connecting lead 2, the first electrode 63, the first signal line 64, the second signal line 65, and the first type of pad 61 sequentially. The light emitting device 71 emits light under the control of the driving chip 72 and the driving signal transmitted through the signal line (first signal line 64 and/or second signal line 65).

As shown in FIG. 7 and FIG. 8, widths (sizes in the first direction X) of the plurality of first electrodes 63 are different from each other, and a width of each first electrode 63 corresponds to a width of a signal line electrically connected to the first electrode 63, such as a width of a second signal line 65. Widths of the first electrodes 63 connected to signal lines of different widths are different from each other.

In some embodiments, the first conductive layer or the second conductive layer is a metal layer including a plurality of stacked structures. For example, the first conductive layer or the second conductive layer includes a titanium layer, a copper layer, and a titanium layer sequentially provided from a side of the substrate 1. Alternatively, the first conductive layer or the second conductive layer includes, for example, a molybdenum layer, a copper layer, or a molybdenum layer sequentially provided from a side of the substrate 1. Alternatively, the first conductive layer or the second conductive layer includes, for example, a molybdenum layer, an aluminum layer, or a molybdenum layer sequentially provided from a side of the substrate 1

In some embodiments, the first conductive layer or the second conductive layer is a signal routing layer of a single-layer structure. Further, the driving line layer is, for example, a copper layer or an aluminum layer, etc.

Specifically, the first conductive layer or the second conductive layer only needs to have a good conductive performance, which is only described exemplarily here and is not used to limit a material adopted for the driving line layer 6.

In some embodiments, as shown in FIG. 6, step S2 (forming the protective layer 3 by adopting the method of multiple printings) includes the following steps S21-S24.

In S21, a first portion 31 of the protective layer 3 is formed on the first surface 1a through at least one printing, as shown in FIG. 7 and FIG. 8.

Exemplarily, in the step of forming the protective layer 3 through printing, a material to form the protective layer 3 is moved onto the substrate 1 through an outlet of a printing device. Since the material to form the protective layer 3 has a certain viscosity, the printing device needs to apply a certain pressure to the material to move the material from the outlet to a corresponding region on the substrate 1. In this way, a size of the material coming out of the outlet in a plane parallel to the outlet is greater than or equal to a size of the outlet. If the outlet is circular, the size of the outlet is an inner diameter of the outlet.

In step S21, as shown in FIG. 7 and FIG. 8, a direction of each printing is, for example, from one side to the other side of the substrate 1 along a first direction X, and the first direction X is parallel to the selected side surface 1cc and parallel to the surface of the substrate 1.

Exemplarily, the first portion 31 of the protective layer 3 includes at least one sublayer.

In some examples, the first portion 31 includes one sublayer. The first portion 31 of the protection layer 3 is formed by the outlet through one printing from one side to the other side of the substrate 1 along the first direction X.

In some other examples, the first portion 31 includes a plurality of sublayers, that is, the first portion 31 of the protective layer 3 is formed by multiple printings. Each printing forms one sublayer of the first portion 31, and each sublayer extends along the first direction X. The plurality of sublayers formed by multiple printings are arranged in sequence along a second direction Y, any two adjacent sublayers are in contact with each other. The second direction Y is perpendicular to the selected side surface 1cc. Any two adjacent sublayers in the plurality of sublayers are referred to as a first sublayer 311 and a second sublayer 312, that is, it may be considered that the first sublayer 311 and the second sublayer 312 alternately provided along the second direction Y are formed by multiple printings.

Along the second direction Y, for example, there is an overlapping of an edge portion of the first sublayer 311 with an edge portion of the second sublayer 312 adjacent to the edge portion of the first sublayer 311. In this way, a gap between two adjacent sublayers is avoided, thereby ensuring that the first portion 31 can completely cover the first lead segment 21.

Since it is necessary to ensure that the pad in the pad layer (e.g., the first type of pad 61 and the second type of pad 62) is electrically connected to the light emitting device 71 and the driving chip 72, the pad cannot be covered by the protective layer 3. A number of printings required to form the first portion 31 of the protective layer 3 can be determined according to a distance between a boundary of the pad layer close to the selected side surface 1cc and the selected side surface 1cc, as well as an inner diameter and an outer diameter of the outlet. The number of printings is at least one, that is, the number of printings may be one or multiple times determined according to an actual situation.

In some examples, a distance between a boundary of an orthographic projection of the pad layer on the substrate 1 close to the selected side surface 1cc and the selected side surface 1cc is, for example, 200 μm, and the first portion 31 of the protective layer 3 is formed through printing using an outlet with an inner diameter of 70 μm and an outer diameter of 150 μm. The first portion 31 is formed on a side of the first lead segment 21 away from the substrate 1 by multiple printings. Printing parameter configurations are: an air pressure 10 psi-20 psi (PSI, Pounds per square inch, pounds/square inch, 1 bar≈14.5 psi, bar hectopascals), a printing speed 30 mm/s˜40 mm/s, and a printing height 10 μm˜15 μm.

It should be noted that the printing parameter configurations mentioned above, such as an air pressure, a printing speed and a printing height, etc., are only used as an exemplary explanation. The width and thickness of the protective layer 3 formed through printing will change as the printing parameter changes. That is, for a sublayer of the protective layer 3 formed by the outlet through one printing along a printing path once, different printing parameter combinations will be used for printing sublayers of different widths and/or thicknesses. Further, the widths of the plurality of sublayers of the protective layer 3 formed by multiple printings may be equal or not completely equal, and the thicknesses of the plurality of sublayers of the protective layer 3 may be equal or not completely equal.

The printing height refers to a distance between the outlet of the printing device and the surface of the substrate 1, and the surface of the substrate 1 includes surfaces of the substrate 1 (the first surface 1a, the second surface 1b and the side surface 1c), and a film layer structure that has been formed on the substrate 1. For example, as shown in FIG. 7, when the first sublayer 311 of the protective layer 3 is formed through printing, the printing height refers to a distance between the outlet and the first surface 1a, the first lead segment 21, the first electrode 63 and the first signal line 64, etc. As shown in FIG. 8, when the second sublayer 312 of the protective layer 3 is formed through printing, the printing height refers to a distance between the outlet and the first surface 1a, an end of the second lead segment 22 toward the first surface 1a and the first sublayer 311, etc.

The printing height is controlled, such that a distance between the outlet and a target coating position is within a certain range. If the printing height is too small, the outlet and the target coating position will interfere with each other (e.g., when forming the second sublayer 312, a distance between the outlet and the first sublayer 311 is too small, such that a material of the protective layer 3 cannot be squeezed out from the outlet onto the substrate 1, and the protective layer 3 cannot be formed at this position; or, a discharge amount is lower than a set discharge amount, such that a thickness of the protective layer 3 at this position is less than a set thickness), thereby affecting a normal discharge of the outlet and causing a formed protective layer 3 (e.g., the first portion 31, the second portion 32, the third portion 33 or the fourth portion 34 of the protective layer 3) to not meet a set requirement. For example, due to interference between the outlet and the target coating position, a thickness and a width of the formed sublayer do not meet a set requirement, or the formed sublayer is not a continuous and complete film layer with a gap, etc., such that the protective layer 3 cannot completely cover the connecting lead 2 and cannot play a target role of the protective layer 3. As shown in FIG. 7, a first sublayer 311 of the first portion 31 is formed through printing along a first path L1. The first sublayer 311 is provided close to the display region AA and the first sublayer 311 covers a plurality of first electrodes 63 and a portion of the first lead segment 21 away from the selected side surface 1cc. Next, as shown in FIG. 8, a second sublayer 312 of the first portion 31 is formed through printing along a second path L2, the second sublayer 312 is provided close to the selected side surface 1cc, and the second sublayer 312 covers a portion of the first lead segment 21 not covered by the first sublayer 311. The first path L1 is parallel or substantially parallel to the second path L2. The first path L1 and the second path L2 both extend along the first direction X, for example.

As shown in FIG. 7 and FIG. 8, a width of the first sublayer 311, h1, is, for example, greater than or equal to an inner diameter of the outlet for printing the first sublayer 311.

As shown in FIG. 8, a width of the second sublayer 312, h2, is, for example, greater than or equal to an inner diameter of the outlet for printing the second sublayer 312.

In some examples, as shown in FIG. 8, a size of a portion where there is an overlapping of the first sublayer 311 with the second sublayer 312 along the second direction Y, h3, is greater than a thickness of a wall of a discharge end and smaller than an outer diameter of the discharge end.

In some other examples, as shown in FIG. 8, a size of a portion where there is an overlapping of the first sublayer 311 with the second sublayer 312 along the second direction Y, h3, is equal to a thickness of a wall of the discharge end.

In yet some examples, as shown in FIG. 8, a size of a portion where there is an overlapping of the first sublayer 311 with the second sublayer 312 along the second direction Y, h3, is smaller than a thickness of a wall of the discharge end and greater than zero.

It should be noted that a thickness of a wall of a discharge end refers to a difference between an outer diameter and an inner diameter of the discharge end. For example, a thickness of a wall of a discharge end with an inner diameter of 70 μm and an outer diameter of 150 μm is 80 μm.

As shown in FIG. 8 and FIG. 9, a thickness of the first sublayer 311 and/or the second sublayer 312 of the first portion 31, d1, is smaller than a thickness of a portion there is an overlapping of the first sublayer 311 with the second sublayer 312, d1′.

When the second sublayer 312 is formed through printing, there is an overlapping of the second sublayer 312 with the first sublayer 311 between a side of the second sublayer 312 away from the selected side surface 1cc and a side of the first sublayer 311 formed earlier close to the selected side surface 1cc, thereby ensuring that the first portion 31 formed through multiple printings can completely cover the first lead segment 21, thereby avoiding the problem of affecting the conductivity of the connecting lead 2 due to water and oxygen corrosion caused by the first lead segment 21 contacting with air and/or water vapor.

In some examples, when the second sublayer 312 is formed through printing along the second path L2, a boundary, away from the display region AA, of an orthographic projection of the discharge end on a plane where the first surface 1a is located exceeds a boundary of the first surface 1a. A range of a distance between the boundary, away from the display region AA, of the orthographic projection of the discharge end on the plane where the first surface 1a is located and the selected side surface 1cc is greater than or equal to the thickness of the wall of the discharge end, and less than or equal to the thickness of the wall of the discharge end by 1.2 times. For example, when the first portion 31 is formed through printing using a discharge end with a thickness of a wall of 80 μm and a sublayer of the first portion 31 closest to the selected side surface 1cc is printed, an outer diameter of the discharge end exceeds a boundary where the first surface 1a intersects with the selected side surface 1cc, and a range of a maximum value of a distance between a portion of the discharge end with its outer diameter exceeding outside the substrate 1 and the selected side surface 1cc is within 80 μm to 96 μm.

It can be understood that when a sublayer of the first portion 31 closest to the selected side surface 1cc is formed through printing, a portion of the discharge end exceeds the boundary of the first surface 1a. In this way, it can be ensured that an intersection position of the first surface 1a with the inner side surface 1cc can be completely covered by the first portion 31, thereby ensuring that the first portion 31 can completely cover the first lead segment 21.

Exemplarily, the first portion 31 covers the first lead segment 21.

A first portion 31 of the protective layer 3 is provided to at least cover the first lead segment 21, thereby avoiding the problem of affecting the conductivity of the first lead segment 21 due to water and oxygen corrosion caused by the first lead segment 21 contacting with air and/or water vapor.

In some examples, the first portion 31 further covers the plurality of first electrodes 63. The first electrode 63 is configured to deliver a driving signal transmitted from the flexible circuit board 5 through the connecting lead 2 to the light emitting device 71.

The first portion 31 covers the first electrode 63 to avoid water and oxygen corrosion due to the first electrode 63 contacting with air and/or water vapor, thereby ensuring the conductivity of the first electrode 63.

In S22, a second portion 32 of the protective layer 3 is formed on the selected side surface 1cc through one printing, as shown in FIG. 5.

In step S22, as shown in FIG. 8, a direction for printing is, for example, along a first direction X from one side to the other side of the substrate 1, and the first direction X is parallel to the selected side surface 1cc and parallel to the surface of the substrate 1.

The second portion 32 includes, for example, one sublayer formed on the selected side surface 1cc through one printing.

Exemplarily, as shown in FIG. 5, FIG. 8 and FIG. 9, when the second portion 32 is formed, the second portion 32 is connected to the first portion 31 at a side of the second portion 32 toward the first portion 31; or, the second portion 32 overlaps with the first portion 31 at a side of the second portion 32 toward the first portion 31. In this way, there will be no gap at an intersection position of the first portion 31 with the second portion 32, and the first lead segment 21 and the second lead segment 22 can be completely covered, thereby avoiding the problem of affecting the conductivity of the connecting lead 2 due to water and oxygen corrosion caused by the first lead segment 21 and the second lead segment 22 contacting with air and/or water vapor.

Exemplarily, a thickness of the substrate 1 is 700 μm. To ensure that the second portion 32 can completely cover the portion of the connecting lead 2 located on the selected side surface 1cc, an outlet with an inner diameter of 800 μm and an outer diameter of 1600 μm is selected to form the second portion 32 of the protective layer 3 through printing. Printing parameter configurations are an air pressure 4 psi˜8 psi, a printing speed 20 mm/s˜30 mm/s, and a printing height 20 μm˜30 μm.

Exemplarily, in the process of forming the second portion 32, a distance between the outlet and the first portion 31 is greater than a thickness of the first portion 31, d1, thereby avoiding interference between the outlet and the first portion 31 when forming the second portion 32.

In S23, a fourth portion 34 of the protection layer 3 is formed on the bonding region BB of the second surface 1b through multiple printings, as shown in FIG. 10.

The fourth portion 34 of the protective layer 3 includes a plurality of capping patterns 341 arranged in parallel and at intervals along the first direction X. A capping pattern 341 is provided on both sides of each fourth lead segment 24, and the capping pattern 341 at least covers a side surface of a corresponding side of the fourth lead segment 24. The first direction X is an arrangement direction of the plurality of fourth lead segments 24 of the plurality of connecting leads 2. For example, the first direction X is parallel to the selected side surface 1cc and parallel to the surface of the substrate 1.

In step S23, as shown in FIG. 10, the path of multiple printings is, for example, from the fan-out region BN toward the bonding region BB along the second direction Y, or from the bonding region BB toward the fan-out region BN along the second direction Y, and the second direction Y is perpendicular to the selected side surface 1cc. Each printing forms one capping pattern 341.

For example, a plurality of capping patterns 341 are formed through multiple printings along a printing path L3 shown in FIG. 11. It can be understood that paths L3 of the multiple printings are different from each other.

Exemplarily, the fourth portion 34 is located at least in the bonding region BB. As shown in FIG. 10, a distance between a boundary of the plurality of capping patterns 341 away from the selected side surface 1cc and the selected side surface 1cc is e1; a distance between a boundary of the plurality of capping patterns 341 close to the selected side surface 1cc and the selected side surface 1cc is e4; a distance between a boundary of the fourth lead segment 24 away from the selected side surface 1cc and the selected side surface 1cc is e2; and a distance between a boundary of the fourth lead segment 24 close to the selected side surface 1cc and the selected side surface 1cc is e3, where e1>e2 and e3>e4.

With such a design, a size of a printing path for the fourth portion 34 along an extension direction of the fourth lead segment 24 (e.g., the Y direction shown in FIG. 10) is greater than an extension length of the fourth lead segment 24, thereby increasing the coverage region of the fourth portion 34. The fourth portion 34 formed through printing along the aforementioned printing path can completely cover a side surface of the fourth lead segment 24 and two ends of the fourth lead segment 24, thereby achieving effective protection of the side surface of the fourth lead segment 24.

In some examples, a range of the difference between e1 and e2, and a range of the difference between e3 and e4 is ½ times to 1 time the inner diameter of the outlet for printing the fourth portion 24.

For example, an outlet with an inner diameter of 70 μm and an outer diameter of 150 μm is selected to form a plurality of capping patterns 341 through printing. The printing parameter configurations are an air pressure 6 psi˜12 psi, a printing speed 20 mm/s˜30 mm/s, and a printing height 4 μm˜6 μm.

The range of the difference between e1 and e2, and the range of the difference between e3 and e4 are from 35 μm to 70 μm.

A size of the fourth lead segment 24 along a direction perpendicular to the selected side surface 1cc (i.e., the second direction Y) is, for example, 1000 μm

A plurality of capping patterns 341 are provided to cover a side surface of the fourth lead segment 24, thereby avoiding the problem of affecting the conductivity of the connecting lead 2 due to water and oxygen corrosion caused by the side surface of the fourth lead segment 24 contacting with air and/or water vapor.

Exemplarily, as shown in FIG. 5 and FIG. 9, a thickness of the fourth portion 34 is less than or equal to 5 μm, and the uniformity of the thickness of the fourth portion 34, d1, is less than or equal to 1 μm. That is, differences in thickness d1 at respective positions of the fourth portion 34 are less than or equal to 1 μm.

It can be understood that the fourth lead segments 24 of the plurality of connecting leads 2 are configured to connect to the flexible circuit board 5, the fourth portion 24 of the protective layer 3 is located between the fourth lead segment 24 and the flexible circuit board 5. Therefore, when the uniformity of the thickness of the fourth portion 34 is poor, a difference in the distances between the surface of the flexible circuit board 5 toward the fourth lead segment 24 and the fourth lead segments 24 of respective connecting leads 2 will be large, thereby making poor stability of the connection of the flexible circuit board 5 with the fourth lead segment 24.

The thickness and the uniformity of the thickness of the fourth portion 34 are controlled, such that the fourth portion 34 of the protective layer 3 does not affect the stability of the connection of the flexible circuit board 5 with the fourth lead segment 24 while effectively protecting the fourth lead segment 24.

In S24, a third portion 33 of the protection layer 3 is formed on the fan-out region BN of the second surface 1b through at least one printing, as shown in FIG. 12.

In step S24, as shown in FIG. 12, a direction for each printing is, for example, along a first direction X from one side to the other side of the substrate 1, and the first direction X is parallel to the selected side surface 1cc and parallel to the surface of the substrate 1.

Exemplarily, the third portion 33 of the protective layer 3 includes at least one sublayer.

In some examples, as shown in FIG. 5, the third portion 33 of the protective layer 3 includes a sublayer, and the third portion 33 of the protective layer 3 is formed by the outlet through one printing from one side to the other side of the substrate 1 along the first direction X.

In some other examples, as shown in FIG. 9, the third portion 33 of the protective layer 3 includes a plurality of sublayers, that is, the third portion 33 of the protective layer 3 is formed through multiple printings, each printing forms one sublayer of the third portion 33, each sublayer extends along a first direction X, and the plurality of sublayers formed through the multiple printings are arranged in sequence along a second direction Y, any two adjacent sublayers are in contact with each other, and the second direction Y is perpendicular to the selected side surface 1cc. Along the second direction Y, there is an overlapping between edge portions of two adjacent sublayers that are close to each other (referring to the description of the first portion 31 for details, which will not be repeated here). In this way, a gap between the two adjacent sublayers can be avoided, thereby ensuring that the third portion 33 can completely cover the third lead segment 23.

As shown in FIG. 9, a thickness of the plurality of sublayers included in the third portion 33 is d3, and a thickness of the portion where there is an overlapping between two adjacent sublayers is d3′, where d3<d3′.

Exemplarily, the remaining film layer structure is not included, at a side of the connecting lead 2 away from the substrate 1, on the connecting lead 2 located in the fan-out region BN (e.g., the third lead segment 23), and a portion of the connecting lead 2 located in the bonding region BB (e.g., the fourth lead segment 24) away from the substrate 1 is connected to the flexible circuit board 5 at a side of the portion of the connecting lead 2 located in the bonding region BB. Therefore, the thickness of the portion of the protective layer 3 located in the fan-out region BN (e.g., the third portion 33), d3, may be greater than or equal to the thickness of the portion of the protective layer 3 located in the bonding region BB (e.g., the fourth portion 34), d4. In this way, while the connecting lead 2 is effectively protected, the overall uniformity of the thickness of all film layers included in the display panel can also be ensured.

A size of the fan-out region BN in a direction perpendicular to the selected side surface 1cc (e.g., the Y direction shown in FIG. 12) is, for example, greater than or equal to 200 μm. For example, the third portion 33 is formed on a side of the third lead segment 23 away from the substrate 1 by using an outlet with an inner diameter of 70 μm and an outer diameter of 150 μm through multiple printings. The printing parameter configurations are an air pressure of 5 psi˜10 psi, a printing speed of 20 mm/s˜30 mm/s, and a printing height of 20 μm˜30 μm.

It should be noted that when the sublayer of the third portion 33 closest to the selected side surface 1cc is formed through printing and when the sublayer is formed by the outlet through printing along the first direction X, the outer diameter of the outlet exceeds a boundary where the second surface 1b intersects with the selected side surface 1cc, and a range of a maximum value of a distance between a portion of the outlet where the outer diameter of the outlet exceeds outside the substrate 1 and the selected side surface 1cc is greater than or equal to the thickness of the outlet, and less than or equal to the wall thickness of the wall of the outlet by 1.2 times. When the sublayer of the third portion 33 farthest from the selected side surface 1cc is formed through printing, there is an overlapping of the sublayer with the fourth portion 34 at a side of the fourth portion 34 close to the sublayer, and a range of the overlapping is the outer diameter of the outlet used by 2 to 3 times.

For example, an outlet with a thickness of a wall of 80 μm is used to form a sublayer of the third portion 33 closest to the selected side surface 1cc through printing, and the outer diameter of the outlet exceeds outside a boundary where the second surface 1b intersects with the selected side surface 1cc, and a range of a maximum value of a distance between a portion where the outer diameter of the outlet exceeds outside the substrate 1 and the selected side surface 1cc is 80 μm to 96 μm. A size of a portion where there is an overlapping between the third portion 33 and the fourth portion 34 along the second direction Y is from 300 μm to 450 μm.

Exemplarily, as shown in FIG. 12, the third portion 33 of the protective layer 3 is a continuous film layer extending along the first direction X.

Exemplarily, as shown in FIG. 9, an edge portion of the third portion 33 is connected to or overlaps with an edge portion of the second portion 32 close to the edge portion of the third portion 33.

Exemplarily, as shown in FIG. 9, an edge portion of the third portion 33 overlaps with an edge portion of the four portion 34 close to the edge portion of the third portion 33.

It can be understood that when the third portion 33 is formed, a boundary of the third portion 33 close to the second portion 32 is connected to or overlaps with the second portion 32, a boundary of the third portion 33 close to the fourth portion 34 overlaps with the fourth portion 34, and a gap existing at a junction position is avoided, thereby ensuring that the connecting lead 2 at a corresponding position can be completely covered and avoiding the problem of affecting the conductivity of the connecting lead 2 due to water and oxygen corrosion caused by a corresponding portion of the connecting lead 2 contacting with air and/or water vapor and then effectively protecting the connecting lead 2.

In some embodiments, step S3 (forming the transfer layer 4 through a method of multiple printings) includes the following step S31.

In S31, a transfer layer 4 is formed on the bonding region BB of the second surface 1b through multiple printings, as shown in FIG. 11. The transfer layer 4 includes a plurality of transfer parts 41. One transfer part 41 is provided between every two adjacent capping patterns 341. The transfer part 41 is connected to the two capping patterns 341 adjacent to the transfer part 41.

Exemplarily, step S31 is after step S23 and before step S24.

Silver paste is, for example, adopted for printing the transfer layer 4, with a viscosity of the silver paste selected from 3000 Pa/s˜5000 mPa/s, thereby ensuring a leveling effect of the silver paste in a gap region between the two capping patterns 341, then ensuring the thickness uniformity of the film layer structure in the bonding region BB, and ensuring the stability of the connection between the flexible circuit board 5 and the transfer layer 4 when the flexible circuit board 5 is bound in the subsequent preparation process.

In step S31, as shown in FIG. 11, the path for multiple printings is, for example, from the fan-out region BN toward the bonding region BB along a second direction Y, or from the bonding region BB toward the fan-out region BN along a second direction Y The second direction Y is perpendicular to the selected side surface 1cc. One transfer part 41 is formed through each printing.

For example, a plurality of transfer parts 41 are formed through multiple printings along a printing path L4 shown in FIG. 11. It can be understood that paths L4 for multiple printings are different from each other.

The size of the outlet and the printing parameters selected for forming the plurality of transfer parts 41 are, for example, the same as those for forming the plurality of capping patterns 341.

As shown in FIG. 13, a distance between a surface of the transfer part 41 away from the substrate 1 and the second surface 1b, e8, is the same or substantially the same as a distance between a surface of the capping pattern 341 away from the substrate 1 and the second surface 1b, e9.

It should be noted that, as shown in FIG. 12, a width of the transfer part 41 in the first direction X may be greater than a spacing between adjacent capping patterns 341, that is, the transfer part 41 may include portions respectively lapping over the surfaces of the capping patterns 341 away from the substrate 1.

As shown in FIG. 12 and FIG. 13, a plurality of transfer parts 41 are provided to fill the gap region between two adjacent capping patterns 341, such that the thicknesses of the film layer structure in the bonding region BB are the same or substantially the same. Secondly, the material of the plurality of transfer parts 41 has good electrical conductivity, and the fourth lead segment 24 is electrically connected to the flexible circuit board 5 through the transfer part 41. A material of the fourth lead segment 24 is, for example, copper, and a material of the transfer part 41 is, for example, silver. The resistivity of silver is lower than that of copper. Under the same size, the resistance value of silver is lower than that of copper. The transfer part 41 is provided to also be beneficial to reducing the resistance value of the connecting line (the overlapping portion of the fourth lead segment 24 with the transfer part 41 is regarded as a whole, as a connecting line for bonding the flexible circuit board 5) while connecting the fourth lead segment 24 and the flexible circuit board 5, thereby beneficial to reducing the power consumption of the display panel.

Exemplarily, as shown in FIG. 11, when a plurality of transfer parts 41 are formed through multiple printings, the outer diameter of the selected outlet is smaller than the spacing between any two adjacent capping patterns 341 along the first direction X, e7.

As shown in FIG. 12, along a direction perpendicular to the selected side surface 1cc, the size of the transfer layer 4 is the same as or substantially the same as the size of the fourth portion 34.

In the display panel formed through the preparation method mentioned above, a protective layer 3 is formed through multiple printings, such that the protective layer 3 can completely cover side surfaces of the first lead segment 21, the second lead segment 22, the third lead segment 23 and the fourth lead segment 24. The transfer layer 4 is formed through multiple printings to cover a portion of the fourth lead segment 24 not covered by the protective layer 3, thereby completely covering the connecting lead 2. In this way, in the process of preparing the display panel, the problem of affecting the conductivity of the connecting lead 2 due to water and oxygen corrosion caused by the plurality of connecting leads 2 contacting with air and/or water vapor, is effectively avoided.

Compared with the preparation method provided in some embodiments, the protective layer 3 and the transfer layer 4 are provided to have a protective effect of the first barrier layer 31′, the second barrier layer 32′ and the third barrier layer 33′ on the connecting lead 2; and have a larger coverage region for the connecting lead 2, thereby achieving a better protective effect. At the same time, the step of forming the third barrier layer 32′ is omitted, thereby avoiding the problems that may occur when the third barrier layer 33′ is removed during the preparation process of the display panel, such as the connecting lead 2 being broken due to a portion of the connecting lead 2 being removed with the third barrier layer 33′, and affecting the connection effect between the connecting lead 2 and the flexible circuit board 5 due to remaining of a portion of the third barrier layer 33′.

Compared with the preparation method provided in some embodiments, the second barrier layer 32′ is provided to cover a portion of the connecting lead 2 that is not covered by the first barrier layer 31′ and the flexible circuit board 5, and this portion is exposed to an outside during the process of connecting the flexible circuit board 5 and the connecting lead 2. During this period, this portion may also be corroded by water and oxygen when contacting with air and/or water vapor, thereby affecting its conductivity. In some embodiments of the present disclosure, by providing a protective layer 3 and a transfer layer 4, the connecting lead 2 is kept in a covered state throughout the entire preparation process, effectively preventing the connecting lead 2 from contacting with air and/or water vapor, thereby better avoiding the problem of affecting the conductivity of the connecting lead 2 due to water and oxygen corrosion on the connecting lead 2.

It should be noted that a number of printings required to form this portion may be determined according to the size of the portion that needs to be covered by a portion of the protective layer 3 (e.g., the first portion 31, the second portion 32, the third portion 33 and the fourth portion 34), and the inner diameter and outer diameter of the outlet used for printing the portion, or, the inner diameter and outer diameter of the outlet used for printing this portion is selected according to the size of the portion that needs to be covered by each portion of the protective layer 3 (e.g., the plurality of capping patterns 341 of the fourth portion 34).

For example, as shown in FIG. 9, the plurality of connecting leads are arranged in parallel along a first direction X, the second lead segment 22 is located on the selected side surface 1cc of the substrate 1, a thickness of the substrate 1 is 700 μm, an outlet with an inner diameter of 800 μm and an outer diameter of 1600 μm is selected, and the outlet is moved from one side to the other side of the selected side surface 1cc of the substrate 1 along the first direction X, that is, the second portion 32 may be formed through one printing.

For another example, as shown in FIG. 10, the fourth portion 34 of the protective layer 3 includes a plurality of capping patterns 341 extending along the second direction Y, each cover 341 covers at least the side surface of the fourth lead segment 24, and a certain spacing needs to be maintained between two adjacent capping patterns 341 (for providing the transfer part 41). It may be understood that a number for printing the fourth portion 34 is related to a number of fourth lead segments 24, and the inner and outer diameters of the outlet used are related to the spacing between adjacent fourth lead segments 24, the width of the fourth lead segment 24 and the width of the transfer part 41. The spacing and the width mentioned here refer to the sizes along the first direction X shown in FIG. 11.

In some embodiments of the present disclosure, a display panel 10 is provided. The display panel 10 may be formed through the preparation method shown in FIG. 3 and FIG. 6.

As shown in FIG. 5, the display panel 10 includes a substrate 1, a plurality of connecting leads 2, a protection layer 3 and a transfer layer 4. The substrate 1 includes a first surface 1a and a second surface 1b that are opposite to each other, and a plurality of side surfaces 1c connecting the first surface 1a and the second surface 1b. The plurality of side surfaces 1c include at least one selected side surface 1cc. The second surface 1b includes a fan-out region BN and a bonding region BB, and the fan-out region BN is closer to the selected side surface 1cc compared to the bonding region BB.

As shown in FIG. 5 and FIG. 11, a connecting lead 2 includes a first lead segment 21 located on the first surface 1a, a second lead segment 22 located on the selected side surface 1cc, and a third lead segment 23 and a fourth lead segment 24 located on the second surface 1b. The first lead segment 21, the second lead segment 22, the third lead segment 23 and the fourth lead segment 24 are connected sequentially. The third lead segment 23 is located in the fan-out region BN, and the fourth lead segment 24 is located in the bonding region BB. The protection layer 3 at least covers side surfaces of the first lead segment 21, the second lead segment 22, the third lead segment 23, and the fourth lead segment 24. The transfer layer 4 covers a surface of the fourth lead segment 24 away from the substrate 1, and is electrically connected to the fourth lead segment 24.

It should be noted that, as shown in FIG. 11, it is an implementation of a plurality of connecting leads 2. Spacings at respective locations between any two adjacent connecting leads 2 in the plurality of connecting leads 2 may be the same as or different from each other.

Exemplarily, as shown in FIG. 5, a material of the substrate 1 is a rigid material such as glass, quartz, plastic, etc.

Exemplarily, as shown in FIG. 5, a material of the connecting lead 2 includes but is not limited to at least one of copper, titanium, aluminum, molybdenum and nickel-gold.

Exemplarily, the substrate 1 further includes a transition surface, and the transition surface includes a first transition subsurface connecting the first surface 1a and the side surface 1c and a second transition subsurface connecting the second surface 1b and the side surface 1c.

In some examples, in a cross section of the substrate 1 along a direction perpendicular to the first surface 1a and perpendicular to a boundary of the substrate 1 where the side surface 1c is located, an angle between a tangent at any point on the first transition subsurface and the first surface 1a is greater than 90°, and an angle between the tangent at any point on the first transition subsurface and the side surface 1c is greater than 90°; and an angle between a tangent at any point on the second transition subsurface and the second surface 1b is greater than 90°, and an angle between the tangent at any point on the second transition subsurface and the side surface 1c is greater than 90°.

For example, the angle formed between the first transition subsurface and the first surface 1a is equal to or approximately equal to the angle formed between the first transition subsurface and the side surface 1c; and the angle formed between the second transition subsurface and the side surface 1c is equal to or approximately equal to the angle formed between the second transition subsurface and the second surface 1b.

In the display panel 10 mentioned above, the protective layer 3 and the transfer layer 4 are provided to cover the plurality of connecting leads 2, thereby avoiding the problem of affecting the conductivity of the connecting lead 2 due to water and oxygen corrosion caused by the connecting lead 2 contacting with air and/or water vapor.

In some embodiments, as shown in FIG. 8 and FIG. 9, the protective layer 3 includes a first portion 31 located on the first surface 1a, and the first portion 31 includes a first sublayer 311 and a second sublayer 312 alternately arranged along a second direction Y. The second direction Y is perpendicular to the selected side surface 1cc. In the second direction Y, an edge portion of the first sublayer 311 overlaps with an edge portion of the second sublayer 312 close to the edge portion of the first sublayer 311.

Exemplarily, as shown in FIG. 7 and FIG. 8, the first portion 31 of the protective layer 3 is formed by adopting multiple printings. For example, multiple printings are adopted to form a plurality of sublayers (e.g., the first sublayer 311 and the second sublayer 312). There is an overlapping between two adjacent sublayers, such that a finally formed first portion 31 is a complete and continuous film layer structure with no gap at positions where the plurality of sublayers are connected.

As shown in FIG. 8, the first portion 31 is formed, for example, by adopting two printings, and a first sublayer 311 extending along the first direction X and a second sublayer 312 extending along the first direction X are formed by two printings, respectively. A width of the first sublayer 311 (e.g., a size along the second direction Y shown in FIG. 8) is h1, and a width of the second sublayer 312 (e.g., a size along the second direction Y shown in FIG. 8) is h2. In the second direction Y, a size of a portion where there is an overlapping of the first sublayer 311 with the second sublayer 312 is h3.

A thickness of the first sublayer 311 and a thickness of the second sublayer 312 are less than or equal to 15 μm, such that a thickness of the display panel 10 is not increased while the protective effect of the first lead segment 21 is ensured, thereby be beneficial to achieving a lightweight design of a display panel.

It can be understood that a thickness of the portion where there is an overlapping of the first sublayer 311 with the second sublayer 312 is greater than a thickness of the first sublayer 311 and/or a thickness of the second sublayer 312. The first sublayer 311 and the second sublayer 312 are formed, for example, by adopting a printing process, and a material for printing has a certain fluidity. It can be understandable that a thickness of the portion where there is the overlapping of the first sublayer 311 with the second sublayer 312 is less than a sum of thicknesses of the first sublayer 311 and the second sublayer 312.

In some embodiments, as shown in FIG. 5 and FIG. 9, the protection layer 3 includes a first portion 31 located on the first surface 1a, a second portion 32 located on the second surface 1b, and a third portion 33 located in the fan-out region BN of the second surface 1b. An edge portion of the first portion 31 is connected or overlaps with an edge portion of the second portion 32 close to the edge portion of the first portion 31. An edge portion of the second portion 32 is connected or overlaps with an edge portion of the third portion 33 close to the edge portion of the first portion 31.

The first portion 31, the second portion 32, the third portion 33 and the fourth portion 34 of the protective layer 3 are formed by, for example, adopting a method of multiple printings, respectively, and one sublayer of the protective layer 3 is formed through one printing. The first portion 31, the second portion 32, the third portion 33 and the fourth portion 34 of the protective layer 3 each include at least one sublayer, and the sublayers formed through multiple printings are connected or overlap with each other at edge portions thereof close to each other. It can be understood that there is no gap at positions where the respective portions (e.g., the first portion 31, the second portion 32, the third portion 33 and the fourth portion 34) included in the protective layer 3 are connected, and the protective layer 3 is a complete and continuous film layer structure, such that the connecting lead 2 can be completely covered, and a protective effect on the connecting lead 2 is achieved.

As shown in FIG. 5, the first portion 31 is formed by adopting, for example, one printing, that is, the first portion 31 is composed of one sub-layer formed by one printing.

As shown in FIG. 9, the first portion 31 is formed by, for example, multiple printings. That is, the first portion 31 is formed by tiling a plurality of sublayers formed through multiple printings, and there is an overlapping between the sublayers and at a side opposite to each other of the sublayers formed through multiple printings. For example, the first portion 3 includes a first sublayer 311 and a second sublayer 312, and the first sublayer 311 overlaps with the second sublayer 312 at edge portions thereof close to each other. A thickness of the first sublayer 311 and/or a thickness of the second sublayer 312 is d3, and a thickness of a portion where there is an overlapping of the first sublayer 311 with the second sublayer 312 is d1′, and d1 is smaller than d1′.

As shown in FIG. 5 and FIG. 9, the second portion 32 is formed by adopting, for example, one printing, that is, the second portion 32 is composed of one sublayer formed by one printing, and the sublayer is connected to or overlaps with an edge portion of the first portion 31 close to the sublayer, thereby ensuring that the connecting lead 2 located at a connection position of the first portion 31 with the second portion 32 can be completely covered by the protective layer 3.

As shown in FIG. 5 and FIG. 12, the third portion 33 is formed by adopting, for example, one printing, that is, the third portion 33 is composed of one sublayer formed by one printing.

As shown in FIG. 9, the third portion 33 is formed by adopting, for example, multiple printings. That is, the third portion 33 is formed by tiling a plurality of sublayers formed through multiple printings, and the sublayers formed through multiple printings overlap with each other at a side where the sublayers are opposite to each other. For example, as shown in FIG. 9, the third portion 33 includes a plurality of sublayers sequentially arranged along the second direction Y, and the plurality of sublayers overlap with each other at a side where the plurality of sublayers are close to each other, where as shown in FIG. 12, the sublayers included in the third portion 33 extend along the first direction X.

It should be noted that a structure of the fourth portion 34 of the protective layer 3 is different from that of the other portions of the protective layer 3. The first portion 31, the second portion 32 and the third portion 33 completely cover the first lead segment 21, the second lead segment 22 and the third lead segment 23, respectively. The fourth portion 34 combined with the transfer layer 4 completely covers the fourth lead segment 24. Specific structures of the fourth portion 34 and the transfer layer 4 are introduced below.

In some embodiments, as shown in FIG. 12, a plurality of fourth lead segments 24 of the plurality of connecting leads 2 are arranged in parallel and at intervals along the first direction X. The protective layer 3 includes a fourth portion 34 located at least in the bonding region BB, and the fourth portion 34 includes a plurality of capping patterns 341 arranged in parallel and at intervals along the first direction X. A capping pattern 341 is provided on both sides of each fourth lead segment 24, and the capping pattern 341 at least covers a side surface of the fourth lead segment 24 at a corresponding side. The transfer layer 4 includes a plurality of transfer parts 41. One transfer part 41 is provided between every two adjacent capping patterns 341. The transfer part 41 is connected to the two capping patterns 341 adjacent to the transfer part 41.

Exemplarily, as shown in FIG. 12, the transfer layer 4 is formed through a direct writing printing process. Further, a plurality of transfer parts 41 are formed through multiple printings.

Exemplarily, a resistivity of a material of the transfer layer 4 is smaller than a resistivity of a material of the connecting lead 2.

Exemplarily, as shown in FIG. 12, the material of the transfer layer 4 is required to be resistant to a high temperature and corrosion and has good electrical conductivity. The material of the transfer layer 4 includes but is not limited to at least one of gold, silver and graphite.

It should be noted that, in the step of forming the transfer layer 4 through a printing process, the material to form the transfer layer 4 is moved onto the substrate 1 through an outlet of a printing device. A material for printing used when the transfer layer 4 is formed through printing is a fluid material, for example, the transfer layer 4 is formed from a resin mixed with nanoparticles of at least one of gold, silver and graphite.

A material resistant to a high temperature and corrosion is adopted for the transfer layer 4. In this way, in the process of preparing the display panel, even if no remaining film layer structure is provided on a side of the transfer layer 4 away from the substrate 1 to protect the transfer layer 4, the performance of the transfer layer 4 itself will not be affected due to being heated in a high temperature in the process of forming a plurality of light emitting devices 71, and the transfer layer 4 will not contact with air and/or water vapor, and water and oxygen corrosion of the transfer layer 4 will not occur. In this way, when the flexible circuit board 5 is connected to the transfer layer 4, the transfer layer 4 can ensure a stable connection between the fourth lead segment 24 and the flexible circuit board 5.

Exemplarily, as shown in FIG. 5, the transfer part 41 is configured to connect the flexible circuit board 5 and the fourth lead segment 24. Along the first direction X, a size of the transfer part 41 is smaller than or equal to a size of the fourth lead segment 24 electrically connected to the the transfer part 41. Each transfer part 41 is provided on a surface of a fourth lead segment 24 away from the substrate 1. An orthographic projection of the transfer part 41 on the substrate overlaps or approximately overlaps with an orthographic projection of the second lead segment 24 on the substrate 1 connected to the transfer part 41.

As shown in FIG. 5 and FIG. 12, the transfer part 41 is provided to cover the portion of the fourth lead segment 24 not covered by the protective layer 3, thereby achieving complete coverage of the connecting lead 2 and then achieving a protective effect on the connecting lead 2. Meanwhile, a conductive material is adopted for the transfer layer 4, which not only achieve a protective effect on the fourth lead segment 24, but also serves to connect the fourth lead segment 24 and the flexible circuit board 5. A resistivity of a material of the transfer layer 4 is lower than a resistivity of a material of the connecting lead 2. Under the same size, a resistance value of the transfer part 41 is lower than a resistance value of the fourth lead segment 24. In this way, the transfer layer 4 is provided to also achieve an effect of reducing the resistance value of a connecting line (the portion where there is an overlapping of the fourth lead segment 24 with the transfer part 41 is regarded as a whole, as a connecting line for bonding the flexible circuit board 5), thereby beneficial to reducing the power consumption of the display panel.

In some embodiments, as shown in FIG. 13, the capping pattern 341 overlaps with an edge portion of the fourth lead segment 24 where a side surface of the fourth lead segment 24 is located, and/or a size of the transfer part 41 along the first direction X is smaller than a size of the fourth lead segment 24 along the first direction X.

The capping pattern 341 is configured to cover a side surface of the fourth lead segment 24 and a gap region between adjacent fourth lead segments 24 to avoid the problem of water and oxygen corrosion on the fourth lead segment 24 due to air and/or water vapor contacting the fourth lead segment 24. The transfer part 41 covers a portion of the fourth lead segment 24 not covered by the capping pattern 341.

It can be understood that when the covering pattern 341 covers a portion of a surface of the fourth lead segment 24, which is close to a side surface of the substrate 1 and is away from the substrate 1, a size of the transfer part 41 covering the fourth lead segment 24 along the first direction X is smaller than a size of the aforementioned fourth lead segment 24 along the first direction X. When the capping pattern 341 only covers the side surface of the fourth lead segment 24, a size of the transfer part 41 covering the fourth lead segment 24 along the first direction X is equal to or greater than a size of the fourth lead segment 24 along the first direction X.

It should be noted that, as shown in FIG. 12, a width of the transfer part 41 along the first direction X may be greater than a spacing between adjacent cover patterns 341, that is, one transfer part 41 may include portions respectively lapping over the surfaces of the cover patterns 341 away from the substrate 1.

In some embodiments, as shown in FIG. 12, the protection layer 3 includes a third portion 33 at least located in the fan-out region BN, and the third portion 33 is a continuous film layer along the first direction X. An edge portion of the third portion 33 away from the selected side surface 1cc overlaps with an edge portion of the capping pattern 341 close to the selected side surface 1cc.

The fourth portion 34 of the protection layer 3 is at least located in the bonding region BB, and the fourth portion 34 at a side toward the selected side surface 1cc also extends toward the selected side surface 1cc. The third portion 33 of the protection layer 3 is at least located in the fan-out region BN, and the third portion 33 at a side away from the selected side surface 1cc also extends toward the bonding region BB.

Exemplarily, the third portion 33 and the fourth portion 34 of the protective layer 3 are formed, respectively. For example, the fourth portion 34 is formed first, then the transfer part 41 is formed, and then the third portion 33 is formed. To ensure effective protection on the connecting lead 2, it is necessary to ensure that the third portion 33 and the fourth portion 34 can completely cover the third lead segment 23 and the fourth lead segment 24. Therefore, when the third portion 33 is formed, there is an overlapping of the third portion 33 at a side away from the selected side surface 1cc with the fourth portion 34 at a side close to the selected side surface 1cc.

In some embodiments, as shown in FIG. 5 and FIG. 9, a thickness of the third portion 33, d3, is less than a thickness of the capping pattern 341, d4.

It should be noted that the capping pattern 341 is configured to be electrically connected to the fourth lead segment 24 and the flexible circuit board 5, respectively. A distance between the substrate 1 and a surface of the capping pattern 341 away from the substrate 1 is the same or substantially the same as a distance between the substrate 1 and a surface of the transfer layer 4 away from the substrate 1.

In this way, it is beneficial to ensuring connection stability between the flexible circuit board 5 and the fourth lead segment 24, thereby ensuring that a driving signal issued from the flexible circuit board 5 can be stably transmitted through the connecting lead 2.

In some embodiments, as shown in FIG. 5 and FIG. 9, a thickness of the fourth portion 34, d4, is less than or equal to 5 μm.

Exemplarily, as shown in FIG. 5 and FIG. 9, a thickness of the third portion 33, d3, is less than or equal to 15 μm.

The protective layer 3 serves as a protective layer for the connecting lead 2, and has the functions of isolating water and oxygen and isolating heat. If the thickness of the protective layer 3 is too small, it will not have an effect of isolating heat. If the thickness is too large, the thickness of the display panel 10 will be increased, and the heat dissipation of the connecting lead 2 will be affected. Therefore, the thickness of the protective layer 3 is required to be ensured within a certain range, such that the thickness of the display panel 10 will not be increased or the heat dissipation of the line of the display panel 10 (e.g., the connecting lead 2) will not be affected while the protective layer 3 can achieve a protective effect on the connecting lead 2.

In some embodiments, as shown in FIG. 10, a boundary of the fourth lead segment 24 away from the selected side surface 1cc is closer to the selected side surface 1cc compared to a boundary of the capping pattern 341 away from the selected side surface 1cc; and/or, a boundary of the fourth lead segment 24 close to the selected side surface 1cc is farther from the selected side surface 1cc compared to a boundary of the capping pattern 341 close to the selected side surface 1cc.

It can be understood that the fourth portion 34 of the protective layer 3 completely covers the side surface of the fourth lead segment 24 of the connecting lead 2, thereby avoiding water and oxygen corrosion due to the side surface of the fourth lead segment 24 contacting with air and/or water vapor and then ensuring the conductive performance of the fourth lead segment 24.

In some embodiments, as shown in FIG. 11, along the first direction X, a maximum value of a spacing between two adjacent capping patterns 341, e5, is less than or equal to a size of the fourth lead segment 24, e6; and a minimum value of a spacing between two adjacent capping patterns 341, e5, is less than or equal to a size of the transfer part 41, e7, by 1.1 times.

Exemplarily, along the first direction X, a size of the transfer part 41, e7, is smaller than or equal to a size of the fourth lead segment 24, e6.

Further, along the first direction X, a size of the transfer part 41, e7, is greater than 90% of a size of the fourth lead segment 24, e6.

The transfer part 41 is configured to connect the fourth lead segment 24 and the flexible circuit board 5. The size of the transfer part 41 needs to be ensured to be within a set range. If the size of the transfer part 41 is too small, its resistance value will be relatively large, thereby increasing the power consumption of the display panel 10.

In some embodiments of the present disclosure, a length of the transfer part 41, for example, a size of the transfer part 41 along a direction perpendicular to the selected side surface 1cc, is slightly larger than a length of the fourth lead segment 24, thereby ensuring that an end of the fourth lead segment 24 can be covered. A width of the transfer part 41, for example, a size of the transfer part 41 along the first direction X shown in FIG. 11, is the same as or approximately the same as the size of the fourth lead segment 24 along the first direction X, thereby ensuring that the resistance value of the transfer part 41 is within a set range, thereby avoiding the problem of increasing of the power consumption of the display panel 10 due to a small size of the transfer part 41.

As shown in FIG. 13, each of two side surfaces of the transfer part 41 along the first direction X is respectively connected to a side surface of one capping pattern 341, thereby completely covering the fourth lead segment 24. It can be understood that when the capping pattern 341 only covers the side surface of the fourth lead segment 24, the size of the transfer part 41 along the first direction X is equal to the size of the fourth lead segment 24 connected thereto. As shown in FIG. 11, when the capping pattern 341 covers the side surface of the fourth lead segment 24 and extends to the surface of the fourth lead segment 24 away from the substrate 1, the size of the transfer part 41 along the first direction X is smaller than the size of the fourth lead segment 24 connected thereto.

The portions of the plurality of connecting leads 2 (e.g., the fourth lead segment 24) located in the bonding region BB are configured to be connected to the flexible circuit board 5, and the side surfaces of the fourth lead segments 24 of the plurality of connecting leads 2 are protected by a plurality of capping patterns 341, and the surface of the fourth lead segment 24 away from the substrate 1 is covered by a transfer part 41, such that the fourth lead segment 24 is completely covered, thereby avoiding the problem of affecting the conductivity of the fourth lead segment 24 due to water and oxygen corrosion caused by the fourth lead segment 24 contacting with air and/or water vapor.

In some embodiments, as shown in FIG. 5, the display panel 10 further includes a flexible circuit board 5 electrically connected to the transfer layer 4.

Further, as shown in FIG. 5, the light emitting device layer includes a plurality of light emitting devices 71, a plurality of driving chip 72 and a protective film 73.

Exemplarily, the display panel 10 includes at least three colors of sub pixels, and various colors of sub pixels include at least a first color of sub pixel, a second color of sub pixel, and a third color of sub pixel. The first color, the second color, and the third color are the three primary colors (e.g., red, green, and blue). Each sub-pixel includes, for example, at least one light emitting device 71.

In some examples, as shown in FIG. 5, the protective film 73 includes a portion covering the plurality of light emitting devices 71 and a portion filling gap regions between the plurality of light emitting devices 71. Exemplarily, a material of the protective film 73 may be black silicone or black resin, etc. The protective film 73 can protect the plurality of light emitting devices 71 and prevent the plurality of light emitting devices 71 from being damaged during the process after forming the light emitting devices 71.

Exemplarily, the light emitting device 71 includes but is not limited to an OLED (Organic Light Emitting Diode), a Mini LED (Mini Light Emitting Diode), a Micro LED (Micro Light Emitting Diode), etc.

In some examples, each light emitting device 71 includes two connection pins, and each driving chip 72 includes six connection pins. The pins of each light emitting device 71 are connected to two first type of pads 61, and the pins of each driving chip 72 are connected to six second type of pads 62, so as to control the light emitting device 71 to emit light under the control of a signal transmitted in a signal line (first signal line 64 and/or second signal line 65) and the driving chip 72.

Exemplarily, as shown in FIG. 7 and FIG. 8, the driving line layer 6 further includes a first conductive layer and a second conductive layer, and the first conductive layer is electrically connected to the second conductive layer. The first conductive layer includes a plurality of first signal lines 64, and the second conductive layer includes a plurality of second signal lines 65. A pad layer is located on a side of the second conductive layer away from the substrate 1, and the pad layer is electrically connected to the second conductive layer.

For example, the first conductive layer or the second conductive layer includes a titanium layer, a copper layer, and a titanium layer sequentially provided from a side of the substrate 1.

Alternatively, the first conductive layer or the second conductive layer includes, for example, a molybdenum layer, a copper layer, and a molybdenum layer sequentially provided from a side of the substrate 1.

Alternatively, the first conductive layer or the second conductive layer includes, for example, a molybdenum layer, an aluminum layer, and a molybdenum layer sequentially provided from a side of the substrate 1.

In some embodiments, the first conductive layer or the second conductive layer is a single-layer signal routing layer. Further, the driving line layer 6 is, for example, a copper layer or an aluminum layer.

Specifically, the first conductive layer or the second conductive layer only needs to have good conductivity. Only an exemplary description is made here and is not to limit a material adopted for the driving line layer 6.

Exemplarily, as shown in FIG. 8, widths (sizes along the first direction X) of the plurality of first electrodes 63 are different from each other, and a width of each first electrode 63 corresponds to a width of a signal line to which the each first electrode 63 is electrically connected, that is, widths of the first electrodes 63 connected to signal lines of different widths are different from each other.

In another aspect, a display apparatus 100 is provided. As shown in FIG. 14, the display apparatus 100 includes the display panel 10 as described in any of the above embodiments and a driving circuit board electrical connected the display panel 10. The driving circuit board is configured to drive the display panel to display a picture.

Exemplarily, an integrated circuit chip is provided on the driving circuit board, and the integrated circuit chip is configured to be electrically connected to the flexible circuit board 5.

In the display apparatus 100, a control signal is issued from the integrated circuit chips, and a driving signal is delivered to the plurality of connecting leads 2 through the flexible circuit board 5, and then delivered to the plurality of first electrodes 63 through the plurality of connecting leads 2. The plurality of first electrodes 63 are configured to achieve electrical connection with the driving line layer 6.

The driving line layer 6 includes, for example, structures, such as a plurality of signal lines (e.g., the first signal line 64 and/or the second signal line 65), etc. The driving line layer 6 is coupled to the light emitting device layer 7 and configured to drive the light emitting device layer 7 to emit light.

Specifically, the plurality of first electrodes 63 receive driving signals transmitted through the plurality of connecting leads 2 and deliver the driving signals to the driving line layer 6, thereby controlling the light emitting devices 71 in the light emitting device layer 7 to emit light, such that the display apparatus 100 displays a picture.

A Mini LED or a Micro LED is adopted as the light emitting device 71. Compared to a traditional LED, the light emitting device 71 occupies a smaller volume and has a smaller particle. Within the same screen size, a density of light sources per unit area is higher and a unit size of the light sources is smaller. Therefore, more precise local control for the light emitting devices 71 can be achieved without the problem of uneven brightness of the light emitting devices 71, such that the uniformity of display brightness can be ensured and thus the display quality of the display apparatus 100 is ensured.

Exemplarily, the driving circuit board 20 is configured to be electrically connected to the flexible circuit board 5. A control signal is issued from the driving circuit board 20, and a driving signal is then delivered to the plurality of connecting leads 2 through the flexible circuit board 5, and delivered to the plurality of first electrodes 63 through the plurality of connecting leads 2. The plurality of first electrodes 63 are configured to achieve electrical connection with the driving line layer 6. The driving line layer 6, for example, includes structures, such as a plurality of signal lines, etc. The driving line layer 6 is coupled to the light emitting device layer 7 and configured to drive the light emitting device layer 7 to emit light. Specifically, the plurality of first electrodes 63 receive driving signals transmitted through the plurality of connecting leads 2 and deliver the driving signals to the driving line layer 6, thereby controlling the light emitting device layer 7 to emit light, such that the display apparatus 100 displays a picture.

Exemplarily, the light emitting device layer 7 further includes a driving chip 72. It can be understood that the driving line layer 6 may also be connected to the driving chip 72, such that the driving chip 72 controls brightness of lighting of the light emitting device 71. Specifically, three light emitting devices 71 may be driven and controlled by a single driving chip 72, which is not limited here.

The display apparatus 100 mentioned above further has the same structure and beneficial technical effects as the display panel 10 provided in some of the embodiments mentioned above, which will not be repeated here.

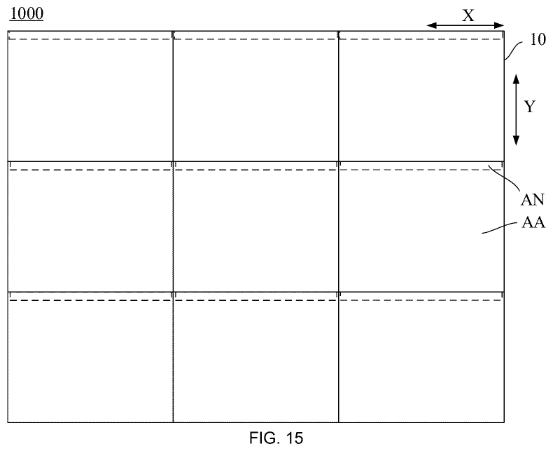

In yet another aspect, a tiled display apparatus 1000 is provided. As shown in FIG. 15, the tiled display apparatus 1000 includes a plurality of display panels 10 tiled to each other as described in any of the embodiments mentioned above.

Exemplarily, as shown in FIG. 15, the display panel 10 is, for example, rectangular.

In some examples, as shown in FIG. 15, the plurality of display panels 10 in the tiled display apparatus 1000 are arranged in an array.

As shown in FIG. 7 and FIG. 8, in the display panel 10, a plurality of first electrodes 63 are arranged in parallel along a first direction X. Correspondingly, a plurality of connecting leads 2 are also arranged in parallel along the first direction X. Another direction parallel to a first surface 1a of the display panel 10 and perpendicular to the first direction X is referred to as a second direction Y.

Exemplarily, as shown in FIG. 5, FIG. 8, and FIG. 15, the display panel 10 includes a display region AA and a peripheral region AN located on a side of the display region AA. The plurality of connecting leads 2 and the plurality of first electrodes 63 are provided close to the peripheral region AN of the substrate 1.

In some examples, as shown in FIG. 5, the display panel 10 includes a selected side surface 1cc.

Further, as shown in FIG. 15, when a plurality of display panels 10 as shown in FIG. 5 are tiled, for example, selected side surfaces 1cc of the plurality of display panels 10 are all provided along the first direction X. In this way, there is basically no seam along the first direction X and between adjacent two display panels 10 in the plurality of display panels 10 arranged in a row along the first direction X; and there is a tiling seam between adjacent two display panels 10 in the plurality of display panels 10 arranged in a column along the second direction Y That is, a size of the tiling seam between adjacent two display panels 10 in the plurality of display panels 10 arranged in a row along the first direction X in a row along the first direction X is smaller than a size of the tiling seam between adjacent two display panels 10 in the plurality of display panels 10 arranged in a column along the second direction Y.

In this way, when viewing the tiled display apparatus 1000, the seam between adjacent two display panels 10 is less noticeable to the naked eye within a viewing distance, such that a display picture of the tiled display apparatus 1000 is more complete and a better display effect is present.

Exemplarily, in the tiled display apparatus 100 shown in FIG. 15, each display panel 10 includes at least three colors of sub pixels, and various colors of sub pixels at least include a first color of sub pixel, a second color of sub pixel, and a third color of sub pixel. The first color, the second color, and the third color are the three primary colors (e.g., red, green, and blue). Each sub-pixel includes, for example, at least one light emitting device 71. A pitch between any two sub pixels is D1, and a pitch between any two display panels 10 in the tiled display apparatus 100 is D2. D1 is the same or approximately the same as D2.

In some examples, a minimum value of a distance between a pixel in each display panel 10 and the side surface 1c is less than or equal to half of D1. For example, D1 is 0.9 mm, D2 is 0.15 mm, 0.225 mm, or 0.45 mm.

The tiled display apparatus 1000 mentioned above further has the same structure and beneficial technical effects as the display panel 10 provided in some of the embodiments mentioned above, which will not be repeated here.

The above is only a specific implementation of the present disclosure, but the scope of protection of the present disclosure is not limited to thereto. Any skilled person familiar with this technical field who thinks of changes or replacements within the technical scope disclosed in the present disclosure should be included in the scope of protection of the present disclosure. Therefore, the scope of protection of the present disclosure should be based on the scope of protection of the claims.

1. A display panel, comprising:
a substrate, comprising a first surface and a second surface opposite to each other, and a plurality of side surfaces connecting the first surface and the second surface, wherein the plurality of side surfaces comprise at least one selected side surface, the second surface comprises a fan-out region and a bonding region, and the fan-out region is closer to the selected side surface compared to the bonding region;
a plurality of connecting leads, wherein the connecting leads comprise a first lead segment located on the first surface, a second lead segment located on the selected side surface, and a third lead segment and a fourth lead segment located on the second surface; the first lead segment, the second lead segment, the third lead segment and the fourth lead segment are connected sequentially; and the third lead segment is located in the fan-out region, and the fourth lead segment is located in the bonding region;
a protective layer, covering at least side surfaces of the first lead segment, the second lead segment, the third lead segment, and the fourth lead segment; and
a transfer layer, covering a surface of the fourth lead segment away from the substrate and electrically connected to the fourth lead segment.

2. The display panel according to claim 1, wherein a plurality of fourth lead segments of the plurality of connecting leads are arranged in parallel and at intervals along a first direction;
the protective layer comprises a fourth portion at least located in the bonding region, the fourth portion comprises a plurality of capping patterns arranged in parallel and at intervals along the first direction, both sides of each fourth lead segment are provided with a capping pattern, and the capping pattern at least cover a side surface of the fourth lead segment at a corresponding side; and
the transfer layer comprises a plurality of transfer parts, one transfer part is provided between every two adjacent capping patterns, and the transfer part is connected to two capping patterns adjacent to the transfer part.

3. The display panel according to claim 2, wherein the capping pattern overlaps with an edge portion where a side surface of the fourth lead segment is located; and/or,
a size of the transfer part in the first direction is less than a size of the fourth lead segment in the first direction.

4. The display panel according to claim 2, wherein the protective layer comprises a third portion at least located in the fan-out region, and the third portion is a continuous film layer along the first direction; and an edge portion of the third portion away from the selected side surface overlaps with an edge portion of the capping pattern close to the selected side surface.

5. The display panel according to claim 4, wherein a thickness of the third portion is greater than a thickness of the capping pattern.

6. The display panel according to claim 5, wherein a thickness of the fourth part is less than or equal to 5 μm.

7. The display panel according to claim 4, wherein a boundary of the fourth lead segment away from the selected side surface is closer to the selected side surface compared to a boundary of the capping pattern away from the selected side surface; and/or
a boundary of the fourth lead segment close to the selected side surface is farther away from the selected side surface compared to a boundary of the capping pattern close to the selected side surface.

8. The display panel according to claim 2, wherein along the first direction, a maximum value of a spacing between two adjacent capping patterns is less than or equal to a size of the fourth lead segment, and a minimum value of a spacing between two adjacent capping patterns is less than or equal to a size of the transfer part by 1.1 times.

9. The display panel according to claim 1, wherein the protective layer comprises a first portion located on the first surface, the first portion comprises a first sublayer and a second sublayer alternately provided along a second direction, and the second direction is perpendicular to the selected side surface; and
along the second direction, an edge portion of the first sublayer overlaps with an edge portion of the second sublayer close to the edge portion of the first sublayer.

10. The display panel according to claim 1, wherein the protective layer comprises a first portion located on the first surface, a second portion located on the second surface, and a third portion located in the fan-out region of the second surface;
an edge portion of the first portion is connected to or overlaps with an edge portion of the second portion close to the edge portion of the first portion;
an edge portion of the second portion is connected to or overlaps with an edge portion of the third portion close to the edge portion of the second portion.

11. The display panel according to claim 1, wherein the display panel further comprises:
a flexible circuit board electrically connected to the transfer layer.

12. The display apparatus, comprising:
a display panel, wherein the display panel comprises:
a substrate, comprising a first surface and a second surface opposite to each other, and a plurality of side surfaces connecting the first surface and the second surface, wherein the plurality of side surfaces comprise at least one selected side surface, the second surface comprises a fan-out region and a bonding region, and the fan-out region is closer to the selected side surface compared to the bonding region;
a plurality of connecting leads, wherein the connecting leads comprise a first lead segment located on the first surface, a second lead segment located on the selected side surface, and a third lead segment and a fourth lead segment located on the second surface: the first lead segment, the second lead segment, the third lead segment and the fourth lead segment are connected sequentially; and the third lead segment is located in the fan-out region, and the fourth lead segment is located in the bonding region;
a protective layer, covering at least side surfaces of the first lead segment, the second lead segment, the third lead segment, and the fourth lead segment; and
a transfer layer, covering a surface of the fourth lead segment away from the substrate and electrically connected to the fourth lead segment; and
a driving circuit board, wherein the driving circuit board is electrically connected to the display panel; and the driving circuit board is configured to drive the display panel to display a picture.

13. A tiled display apparatus, comprising a plurality of display panels tiled to each other according to claim 1.

14. A preparation method for a display panel, comprising:
forming a plurality of connecting leads on a substrate, wherein the substrate comprises a first surface, a second surface, and a plurality of side surfaces connecting the first surface and the second surface, the plurality of side surfaces comprises at least one selected side surface, the second surface comprises a bonding region and a fan-out region, the fan-out region is closer to the selected side surface compared to the bonding region; the connecting leads comprise a first lead segment located on the first surface, a second lead segment located on the selected side surface, and a third lead segment and a fourth lead segment located on the second surface; the first lead segment, the second lead segment, the third lead segment and the fourth lead segment are connected sequentially; and the third lead segment is located in the fan-out region, and the fourth lead segment is located in the bonding region;
forming a protective layer by adopting a method of multiple printings, wherein the protective layer at least covers side surfaces of the first lead segment, the second lead segment, the third lead segment, the fourth lead segment; and
forming a transfer layer, wherein the transfer layer covers a surface of the fourth lead segment away from the substrate and is electrically connected to the fourth lead segment.

15. The preparation method for a display panel according to claim 14, wherein the forming the protective layer by adopting the method of multiple printings and the forming the transfer layer comprises:
forming a first portion of the protective layer on the first surface through at least one printing;
forming a second portion of the protective layer on the selected side surface through one printing;
forming a fourth portion of the protective layer on the bonding region of the second surface through multiple printings; wherein the fourth portion comprises a plurality of capping patterns arranged in parallel and at intervals along a first direction, and both sides of each fourth lead segment are provided with a capping pattern, and the capping patterns at least cover a side surface of the fourth lead segment at a corresponding side; and the first direction is an arrangement direction of a plurality of fourth lead segments of the plurality of connecting leads;
forming a transfer layer on the bonding region of the second surface through multiple printings; wherein the transfer layer comprises a plurality of transfer parts, one transfer part is provided between every two adjacent capping patterns, and the transfer part is connected to the two cover parts adjacent to the transfer part; and
forming a third portion of the protection layer on the fan-out region of the second surface through at least one printing.

16. The display panel according to claim 2, wherein the protective layer comprises a first portion located on the first surface, the first portion comprises a first sublayer and a second sublayer alternately provided along a second direction, and the second direction is perpendicular to the selected side surface; and
along the second direction, an edge portion of the first sublayer overlaps with an edge portion of the second sublayer close to the edge portion of the first sublayer.

17. The display panel according to claim 3, wherein the protective layer comprises a first portion located on the first surface, the first portion comprises a first sublayer and a second sublayer alternately provided along a second direction, and the second direction is perpendicular to the selected side surface; and
along the second direction, an edge portion of the first sublayer overlaps with an edge portion of the second sublayer close to the edge portion of the first sublayer.

18. The display panel according to claim 4, wherein the protective layer comprises a first portion located on the first surface, the first portion comprises a first sublayer and a second sublayer alternately provided along a second direction, and the second direction is perpendicular to the selected side surface; and
along the second direction, an edge portion of the first sublayer overlaps with an edge portion of the second sublayer close to the edge portion of the first sublayer.

19. The display panel according to claim 2, wherein the protective layer comprises a first portion located on the first surface, a second portion located on the second surface, and a third portion located in the fan-out region of the second surface;
an edge portion of the first portion is connected to or overlaps with an edge portion of the second portion close to the edge portion of the first portion;
an edge portion of the second portion is connected to or overlaps with an edge portion of the third portion close to the edge portion of the second portion.

20. The display panel according to claim 3, wherein the protective layer comprises a first portion located on the first surface, a second portion located on the second surface, and a third portion located in the fan-out region of the second surface;
an edge portion of the first portion is connected to or overlaps with an edge portion of the second portion close to the edge portion of the first portion;
an edge portion of the second portion is connected to or overlaps with an edge portion of the third portion close to the edge portion of the second portion.
